(19) United States
(12) Patent Application Publication
(10) Pub. No.: US 2023/0399253 A1
(43) Pub. Date: Dec. 14, 2023

(54) GLASS SUBSTRATE

(71) Applicant: Nippon Electric Glass Co., Ltd., Shiga (JP)

(72) Inventor: Masaki MAKITA, Shiga (JP)

(21) Appl. No.: 18/033,475

(22) PCT Filed: Nov. 9, 2021
(86) PCT No.: PCT/JP2021/041107

§ 371 Date: Apr. 24, 2023

(30) Foreign Application Priority Data
Nov. 16, 2020 (JP) 2020-190229

(51) Int. Cl. C03C 3/118

(52) U.S. Cl. CPC C03C 3/118; H01L 23/15

(57) ABSTRACT

A glass substrate of the present invention includes a glass composition containing from 65.0 to 80.0 mol % of SiO₂, from 2.0 to 15.0 mol % of Al₂O₃, from 0 to 15.0 mol % of B₂O₃, from 0.001 to less than 0.1 mol % of Li₂O+Na₂O+K₂O, from 0 to 15.0 mol % of MgO, from 0 to 15.0 mol % of CaO, from 0 to 15.0 mol % of SrO, from 0 to 15.0 mol % of BaO, from 0.01 to 1.0 mol % of SnO₂, from 0 to less than 0.050 mol % of As₂O₃, and from 0 to less than 0.050% of Sb₂O₃.

### TECHNICAL FIELD

The present invention relates to a glass substrate, and more particularly to a glass substrate suitable for a micro LED display.

### BACKGROUND ART

A tiling-type micro LED display has been developed (see Patent Document 1). In this type of display, a plurality of display panels using micro LEDs as light-emitting elements are arranged to form one display.

In a tiling-type micro LED display, it is necessary to make the borders between tiles to be less recognizable. For this reason, a driving unit can not be arranged in a peripheral portion of a glass substrate as it has been done in a display known in the art. Therefore, a light-emitting element on each tile needs to be driven from the rear surface side of the glass substrate, and, in this case, a through hole needs to be formed in the thickness direction of the glass substrate to allow electrical connection to be established between the front and rear surfaces of the glass substrate.

As a method of forming a through hole in the thickness direction of the glass substrate, for example, such a method is known that a modified portion is produced inside the glass substrate by irradiation with laser light, and then removed by HF etching, forming a through hole (see Patent Document 2). The through hole formed by this method has a tapered shape in a cross-sectional view.

### CITATION LIST

### Patent Literature

Patent Document 1: JP 2018-205525 A
Patent Document 2: JP 6333282 B

### SUMMARY OF INVENTION

### Technical Problem

When pixel density increases due to the high definition of display, the wiring density also increases at the same time, and accordingly, it is important to reduce a taper angle of the through hole.

The taper angle of the through hole is considered to be determined by the ratio of an expansion rate of the hole in the substrate thickness direction during etching to a rate of expansion of the hole diameter. Decreasing the rate of expansion of the hole diameter can reduce the taper angle. The rate of expansion rate of the hole diameter is synonymous with the HF etching rate of mother glass. Therefore, it is important to reduce the HF etching rate in order to form a through hole having a small taper angle. Increasing the SiO₂ content in a glass composition reduces the HF etching rate.

In addition, a glass substrate for display applications is becoming less expensive. In order to make the glass substrate inexpensive, it is important to improve the productivity (meltability, formability, devitrification resistance) and to improve its surface quality by forming the glass substrate by an overflow down-draw method. However, as described above, increasing the SiO₂ content may lower the meltability, increasing the melting cost. Further, a forming temperature becomes higher, and a forming body used in the overflow down-draw method tends to have shorter lifetime. As a result, the cost of an original plate for the glass substrate increases.

Further, when glass components other than SiO₂ are adjusted to improve the productivity of the glass substrate, phase-separation of glass tends to occur. When the glass is phase-separated, the transmittance decreases; in addition, cloudiness or unevenness tends to occur on the glass surface during HF etching. As a result, it may not be used for display applications.

The present invention has been made in view of the above circumstances, and a technical object is to provide a glass substrate that has a low HF etching rate, is hardly phase-separated, and is excellent in productivity.

### Solution to Problem

As a result of repeating various experiments, the present inventor has found that the above technical issue can be solved by strictly regulating the glass composition of a glass substrate, and proposes the findings as the present invention. A glass substrate according to an embodiment of the present invention includes a glass composition containing from 65.0 to 80.0 mol % of SiO₂, from 2.0 to 15.0 mol % of Al₂O₃, from 0 to 15.0 mol % of B₂O₃, from 0.001 to less than 0.1 mol % of Li₂O+Na₂O+K₂O, from 0 to 15.0 mol % of MgO, from 0 to 15.0 mol % of CaO, from 0 to 15.0 mol % of SrO, from 0 to 15.0 mol % of BaO, from 0 to 1.0 mol % of SnO₂, from 0 to less than 0.050 mol % of As₂O₃, and from 0 to less than 0.050% of Sb₂O₃. Note that “Li₂O+Na₂O+K₂O” means a total content of Li₂O, Na₂O, and K₂O.

Also, the glass substrate according to an embodiment of the present invention preferably includes a glass composition containing from 69.6 to 80.0 mol % of SiO₂, from 7.1 to 13.0 mol % of Al₂O₃, from 2.0 to 7.5 mol % of B₂O₃, from 0.001 to less than 0.1 mol % of Li₂O+Na₂O+K₂O, from 3.4 to 10.0 mol % of MgO, from 0.1 to 5.5 mol % of CaO, from 0.1 to 15.0 mol % of SrO, from 0.3 to 3.0 mol % of BaO, from 0.01 to 1.0 mol % of SnO₂, from 0 to less than 0.050 mol % of As₂O₃, and from 0 to less than 0.050% of Sb₂O₃.

Also, the glass substrate according to an embodiment of the present invention preferably includes a glass composition containing from 69.6 to 80.0 mol % of SiO₂, from 7.1 to 12.5 mol % of Al₂O₃, from 2.7 to 7.5 mol % of B₂O₃, from 0.001 to less than 0.1 mol % of Li₂O+Na₂O+K₂O, from 3.4 to 10.0 mol % of MgO, from 0.1 to 5.5 mol % of CaO, from 0.5 to 3.8 mol % of SrO, from 0.3 to 3.0 mol % of BaO, from 0.01 to 1.0 mol % of SnO₂, from 0 to less than 0.050 mol % of As₂O₃, and from 0 to less than 0.050% of Sb₂O₃.

Also, the glass substrate according to an embodiment of the present invention preferably includes a glass composition containing from 69.7 to 80.0 mol % of SiO₂, from 2.0 to 15.0 mol % of Al₂O₃, from 2.5 to 15.0 mol % of B₂O₃, from 0.001 to less than 0.1 mol % of Li₂O+Na₂O+K₂O, from 0 to 15.0 mol % of MgO, from 0 to 8.2 mol % of CaO, from 0 to 15.0 mol % of SrO, from 1.1 to 15.0 mol % of BaO, from 0.01 to 1.0 mol % of SnO₂, from 0.0005 to 0.1 mol % of TiO₂, from 0 to less than 0.050% of As₂O₃, and from 0 to less than 0.050% of Sb₂O₃.

Also, the glass substrate according to an embodiment of the present invention preferably has an HF etching rate of 3.00 μm/min or less. Here, the “HF etching rate” refers to a value measured by the following method. First, a sample was optically polished on both its surfaces, and then annealed and partially masked. A 2.5 mol/L of HF solution (300 mL) was set to have a temperature of 30° C. using a water bath stirrer, and stirred at about 600 rpm. A glass substrate was immersed in this HF solution for 20 minutes. Thereafter, the mask was removed, the sample was washed, and a level difference between a masked portion and an eroded portion was measured with a Surfcorder (ET4000A, available from Kosaka Laboratory Ltd.). The etching rate was calculated by dividing the value by the immersion time.

In the glass substrate according to an embodiment of the present invention, a temperature at which a high-temperature viscosity is 10^{2.5} dPa·s is 1760° C. or lower. The “temperature at which the high-temperature viscosity is 10^{2.5} dPa·s” can be measured, for example, by a platinum sphere pull up method.

The glass substrate according to an embodiment of the present invention preferably has a through hole.

The glass substrate according to an embodiment of the present invention is preferably used in a micro LED display.

### Advantageous Effects of Invention

According to the present invention, it is possible to provide a glass substrate that has a low HF etching rate, is hardly phase-separated, and is excellent in productivity.

### BRIEF DESCRIPTION OF DRAWINGS

FIG. 1 is a schematic cross-sectional view of a glass substrate having a modified portion formed in the substrate thickness direction.

FIG. 2 is a schematic cross-sectional view of the glass substrate during an etching process.

FIG. 3 is a schematic cross-sectional view of a glass substrate having a through hole.

FIG. 4 is a schematic cross-sectional view of a glass substrate in which a narrowed portion inside a through hole is not located at a center portion in the substrate thickness direction.

FIG. 5 is a schematic cross-sectional view of a glass substrate having no narrowed portion inside a through hole.

### DESCRIPTION OF EMBODIMENTS

A glass substrate according to an embodiment according to an embodiment of the present invention is characterized by including a glass composition containing from 65.0 to 80.0 mol % of SiO₂, from 2.0 to 15.0 mol % of Al₂O₃, from 0 to 15.0 mol % of B₂O₃, from 0.001 to less than 0.1 mol % of Li₂O+Na₂O+K₂O, from 0 to 15.0 mol % of MgO, from 0 to 15.0 mol % of CaO, from 0 to 15.0 mol % of SrO, from 0 to 15.0 mol % of BaO, from 0 to 1.0 mol % of SnO₂, from 0 to less than 0.050 mol % of As₂O₃, and from 0 to less than 0.050% of Sb₂O₃. The reason for limiting the content of each component as described above is as follows. Note that in the description of the content of each component, “%” represents “mol %” unless otherwise indicated.

SiO₂ is a component that forms a glass network. When a content of SiO₂ is too small, chemical resistance lowers. In particular, the HF etching rate increases, and thus the expansion rate of the hole diameter when the through hole is formed increases, and the taper angle of the through hole increases. Therefore, a lower limit amount of SiO₂ is 65.0%, more preferably 68.0%, even more preferably 68.6%, even still more preferably 68.8%, further preferably 68.9%, further more preferably 69.1%, still further more preferably 69.6%, even still further more preferably 69.7%, and particularly preferably 69.9%. SiO₂ is a component which dissolves in an HF solution and does not cause a residue when the glass substrate is etched with the HF solution. Therefore, by increasing the SiO₂ content in the glass, an amount of the residue remained during etching decreases, the clogging due to a residue hardly occurs in an etching apparatus, a load during treatment of the residue is reduced, and the cost required for treating the residue is reduced. In particular, when the SiO₂ content is 69.7% or more, the above-described effects are enhanced, the HF etching rate is lowered, and the taper angle of the through hole may be reduced. Meanwhile, when the SiO₂ content is too large, the viscosity in high temperature increases, an amount of heat required during melting increases, a melting cost increases, and an unmelted raw material for introducing SiO₂ is generated, which may cause a decrease in yield. As such, an upper limit amount of SiO₂ is 80.0%, more preferably 78.0%, even more preferably 76.0%, even still more preferably 75.8%, further preferably 75.5%, further more preferably 75.3%, and particularly preferably 75.1%.

Al₂O₃ is a component that forms a glass network, and is also a component that increases chemical resistance. When a content of Al₂O₃ is too small, chemical resistance decreases, and, in particular, the HF etching rate tends to increase. Therefore, a lower limit amount of Al₂O₃ is 2.0%, more preferably 5.2%, even more preferably 7.1%, even still more preferably 7.3%, further preferably 7.5%, further more preferably 7.7%, even further more preferably 8.0%, even still further more preferably 8.6%, even still further more preferably 8.7%, even still further more preferably 8.8%, even still further more preferably 8.9%, even still further more preferably 9.0%, and particularly preferably 9.1%. Meanwhile, when the Al₂O₃ content is too large, the amount of the residue generated increases according to an amount of the substrate thickness reduced during HF etching, and, for example, the residue tends to clog the etching apparatus. Therefore, an upper limit amount of Al₂O₃ is 15.0%, more preferably 13.0%, even more preferably 12.9%, even still more preferably 12.5%, further preferably 12.3%, further more preferably 12.0%, even further more preferably 11.8%, even still further more preferably 11.5%, even still further more preferably 11.0%, even still further more preferably 10.9%, and particularly preferably 10.5%.

B₂O₃ is a component that increases meltability and devitrification resistance. When the B₂O₃ content is too small, meltability and devitrification resistance tend to decrease. Therefore, a lower limit amount of B₂O₃ is 0%, preferably 0.1%, more preferably 0.5%, even more preferably 0.6%, even still more preferably 1.0%, further preferably 1.5%, further more preferably 2.0%, even further more preferably 2.1%, even still further more preferably 2.5%, even still further more preferably 2.7%, even still further more preferably 2.8%, even still further more preferably 3.1%, even still further more preferably 3.4%, even still further more preferably 3.5%, and particularly preferably 4.0%. B₂O₃ is a component that dissolves in an HF solution and does not cause a residue when the glass substrate is etched with the HF solution. Therefore, including B₂O₃ in a glass reduces the amount of the residue due to etching decreases, which means that the residue clogging hardly occurs in an etching apparatus, a load during treatment of the residue is reduced, and the cost required for dealing with the residue is reduced. In particular, when the B₂O₃ content is 2.5% or more, the above-described effects are easily obtained. Meanwhile, when the B₂O₃ content is too large, phase separation of glass tends to occur. When the glass is phase-separated, the glass substrate becomes cloudy, and the transmittance of the glass substrate decreases. In addition, even in the case where cloudiness is not confirmed, the glass surface tends to become cloudy during HF etching due to the influence of phase separation, and unevenness tends to occur on the glass surface. Further, a phase-separated region having a small amount of SiO₂ is generated, and the HF etching rate increases. Therefore, an upper limit amount of B₂O₃ is 15.0%, more preferably 10.0%, even more preferably 7.5%, even still more preferably 7.4%, further preferably 7.3%, further more preferably 7.0%, still further more preferably 6.5%, even still further more preferably 6.0%, even still further more preferably 5.5%, and particularly preferably 5.0%.

Li₂O, Na₂O and K₂O are components that unavoidably get mixed in from glass raw materials, and a total content or individual contents thereof is/are from 0.001 to less than 0.1%, preferably from 0.005 to 0.09%, and more preferably from 0.01 to 0.05%. When the total amount or individual contents of Li₂O, Na₂O and K₂O is/are too large, alkali ions may diffuse into a semiconductor material deposited during a heat treatment process.

MgO is a component that improves HF resistance, and is also a component that lowers viscosity in high temperature and increases meltability. When the MgO content is too small, the HF etching rate tends to increase, and the taper angle of the through hole tends to increase. Further, meltability tends to decrease. In addition, Young's modulus decreases, and the glass substrate tends to be bent, and, as a result, the glass substrate tends to be easily broken. Therefore, a lower limit amount of MgO is 0%, more preferably 1.0%, even more preferably 1.1%, even still more preferably 1.1%, further preferably 3.0%, further more preferably 3.4%, still further more preferably 3.5%, and particularly preferably 4.0%. In particular, when the MgO content is 3.4% or more, a through hole having a small taper angle tends to be formed. Meanwhile, when the content of MgO is too large, phase separation of glass tends to occur. In addition, devitrified crystals such as mullite tend to be produced, and a liquid phase viscosity tends to decrease. Therefore, an upper limit amount of MgO is 15.0%, more preferably 13.8%, even more preferably 13.7%, even still more preferably 13.8%, further preferably 13.0%, further more preferably 11.9%, even further more preferably 11.0%, even still further more preferably 10.0%, even still further more preferably 9.9%, even still further more preferably 9.5%, and particularly preferably 9.0%.

CaO is a component that lowers the viscosity in high temperature and increases meltability. When the content of CaO is too small, the above effects become hard to obtain. As such, a lower limit amount of CaO is preferably 0%, more preferably 0.1%, even more preferably 0.2%, even still more preferably 0.5%, and particularly preferably 1.0%. Meanwhile, when the CaO content is too large, phase separation of glass tends to occur. In addition, the amount of the residue generated during etching increases, and the residue tends to accumulate inside some of the holes. As a result, the etching rate in a depth direction of the holes decreases, and shapes of the holes tend to vary. In addition, residue clogging tends to occur in the etching apparatus, and a load during treatment of the residue increases. A mass of the residue generated then is proportional to a formula weight of a salt composed of an alkaline earth metal, Al, and F. Therefore, as an atomic weight of the alkaline earth metal is larger, this issue is more likely to reveal. Forming a through hole by etching in particular causes a residue corresponding to an amount of the substrate thickness etched in addition to the volume of the through hole. Making many through holes causes a residue in proportion to the number of through holes. Therefore, even for glass substrates that did not have problems in a known slimming process, the above-described issues become apparent, increasing the manufacturing costs. Therefore, an upper limit amount of CaO is 15.0%, more preferably 10.0%, even more preferably 8.5%, even still more preferably 8.2%, further preferably 8.0%, further more preferably 5.5%, even further more preferably 5.4%, even still further more preferably 5.3%, even still further more preferably 5.0%, even still further more preferably 4.5%, and particularly preferably 4.0%. In particular, when the CaO content is 5.5% or less, the above issue over the residue may be easily solved.

SrO is a component that lowers the viscosity in high temperature and increases meltability. When the content of SrO is too small, the above effects become hard to obtain. Therefore, a lower limit amount of SrO is 0%, more preferably 0.1%, even more preferably 0.2%, even still more preferably 0.5%, further preferably 0.6%, further more preferably 0.7%, still further more preferably 0.8%, even still further more preferably 0.9%, even still further more preferably 1.0%, even still further more preferably 1.5%, even still further more preferably 2.0%, and particularly preferably 2.2%. Meanwhile, when the SrO content is too large, phase-separation of glass tends to occur. Also, the amount of the residue increases, and the above-described issue over the residue occurs; the shapes of the holes tend to vary, increasing the manufacturing costs. Therefore, an upper limit amount of SrO is 15.0%, more preferably 12.0%, even more preferably 10.0%, even still more preferably 5.0%, further preferably 4.0%, further more preferably 3.9%, still further more preferably 3.8%, even still further more preferably 3.5%, even still further more preferably 3.1%, and particularly preferably 3.0%. In particular, when the SrO content is 3.8% or less, the above issue over the residue may be easily solved.

BaO is a component that increases the devitrification resistance, and is also a component that makes phase-separation of glass difficult. When the content of BaO is too small, the above effects become hard to obtain. Therefore, a lower limit amount of BaO is 0%, more preferably 0.1%, even more preferably 0.3%, even still more preferably 0.4%, further preferably 0.5%, further more preferably 0.8%, even further more preferably 0.9%, even still further more preferably 1.0%, even still further more preferably 1.1%, even still further more preferably 1.4%, even still further more preferably 1.5%, even still further more preferably 2.0%, and particularly preferably 2.1%. Meanwhile, when a content of BaO is too large, the HF etching rate tends to increase. In addition, as the mass of a residue increases, the above-described issue over the residue occurs. As a result, the shapes of the holes tend to vary, increasing the manufacturing costs. As such, an upper limit amount of BaO is 15.0%, more preferably 10.0%, even more preferably 5.0%, even still more preferably 3.0%, further preferably 2.9%, further more preferably 2.8%, and particularly preferably 2.5%. In particular, when the BaO content is 3.0% or less, the above issue over the residue may be easily solved.

SnO₂ is a component that has a good fining action in a high temperature range, and is a component that lowers the viscosity in high temperature and increases the meltability. Therefore, in order to produce the glass substrate with high yield, it is essential to blend SnO₂, the content of which is preferably from 0 to 1.0%, more preferably from 0.01 to 0.8%, even more preferably from 0.01 to 0.5%, and particularly preferably from 0.05 to 0.5%. Note that when the SnO₂ content is less than 0.01%, the above effects become hard to obtain. When the SnO₂ content is too large, devitrified crystals of SnO₂ tend to precipitate, which may cause a decrease in yield.

TiO₂ is a component that lowers the viscosity in high temperature and increases the meltability, and is also a component that increases the absorbance in an ultraviolet region. When the absorbance in the ultraviolet region, particularly the absorbance in a deep ultraviolet region, is high, the multiphoton absorption tends to occur upon irradiation with a femtosecond or picosecond laser, and the formation of a modified portion in the glass becomes easy. Therefore, introducing TiO₂ is advantageous when a laser modified portion is formed in a glass substrate and removed by subsequent etching to form a through hole in the glass substrate. As such, a lower limit amount of TiO₂ is preferably 0%, more preferably 0.0005%, even more preferably 0.001%, and particularly preferably 0.005%. Meanwhile, including a large amount of TiO₂ may cause the glass substrate to be colored, and the transmittance of the glass substrate tends to decrease. As such, when the glass substrate is used in a display application, an upper limit value of TiO₂ is preferably 0.1%, more preferably less than 0.1%, even more preferably 0.08%, and particularly preferably 0.05%.

ZnO is a component that increases the meltability. However, including a large amount of ZnO may cause the glass substrate to be colored, and the transmittance of the glass substrate tends to decrease. As such, when the glass substrate is used in a display application, a content of ZnO is desirably lower, and its content is preferably from 0 to less than 0.4%, more preferably from 0 to 0.3%, even more preferably from 0 to 0.2%, and particularly preferably from 0 to 0.1%.

In addition to the above components, the following components may be added as an optional component, for example. Note that a total content of other components in addition to the components described above is preferably 5% or less, particularly preferably 1% or less, from the viewpoint of accurately achieving the effects of the present invention.

P₂O₅ is a component that improves HF resistance. However, when a large amount of P₂O₅ is contained, phase separation of glass tends to occur. The P₂O₅ content is preferably from 0 to 2.5%, more preferably from 0.0005 to 1.5%, even more preferably from 0.001 to 0.5%, and particularly preferably from 0.005 to 0.3%.

CuO is a component that colors glass. As such, when the glass substrate is used in a display application, a content of CuO is desirably lower, and its content is preferably from 0 to 0.1%, more preferably from 0 to less than 0.1%, and particularly preferably from 0 to 0.05%.

Y₂O₃, Nb₂O₅ and La₂O₃ are components that improve mechanical properties such as Young's modulus; however, when a total content and individual content of these components is too large, raw material costs tend to increase. A total content and individual contents of Y₂O₃, Nb₂O₅ and La₂O₃ is/are preferably from 0 to 5%, more preferably from 0 to 1%, even more preferably from 0 to 0.5%, and particularly preferably 0 or greater and less than 0.5%.

As mentioned above, SnO₂ is suitable as a fining agent. However, as long as the glass properties are not compromised, up to 1% (preferably up to 0.8%, particularly up to 0.5%) each of F, SO₃, C, or a metal powder such as Al or, Si can be added, instead of SnO₂ or together with SnO₂, as the fining agent. CeO₂ can also be added as a fining agent; however, when the CeO₂ content is too large, coloring of glass occurs, and as such, an upper limit of the content is preferably 0.1%, more preferably 0.05%, and particularly preferably 0.01%.

As₂O₃ and Sb₂O₃ are also effective as fining agents. However, As₂O₃ and Sb₂O₃ are components that increase the burden to the environment. As such, the glass substrate according to an embodiment of the present invention preferably does not substantially contain these components, and ranges for contents of As₂O₃ and Sb₂O₃ are each from 0 to less than 0.050%.

Cl is a component that facilitates initial melting of a glass batch. Additionally, the addition of Cl can facilitate the action of the fining agent. As a result, it is possible to extend the life of the glass manufacturing kiln while reducing the melting cost. However, when the Cl content is too large, a strain point tends to decrease; accordingly, when such a glass substrate is used in a display application, issues such as total pitch deviation may occur. As such, the content of Cl is preferably from 0 to 3%, more preferably from 0.0005 to 1%, and particularly preferably from 0.001 to 0.5%. Note that, as a raw material for introducing Cl, a raw material such as a chloride of an alkaline earth metal oxide, an example being strontium chloride, or aluminum chloride can be used.

Fe₂O₃ is a component that unavoidably gets mixed in from glass raw materials, and is also a component that colors glass. When the Fe₂O₃ content is too small, raw material costs tend to increase. Meanwhile, when the Fe₂O₃ content is too large, the glass substrate is colored and may not be used in a display application. The Fe₂O₃ content is preferably from 0 to 300 mass ppm, more preferably from 80 to 250 mass ppm, and particularly preferably from 100 to 200 mass ppm.

ZrO₂ is a component irreversibly mixed from a refractory used in the glass manufacturing kiln. When the ZrO₂ content is too large, devitrified crystals tend to precipitate. Meanwhile, in order to reduce the ZrO₂ content, the melting temperature must be lowered, and, in this case, melting of the glass becomes difficult. The ZrO₂ content is preferably from 0 to 0.5%, more preferably from 0.0001 to 0.5%, even more preferably from 0.001 to 0.4%, and particularly preferably from 0.005 to 0.3%.

The glass substrate according to an embodiment of the present invention preferably has the following properties.

The HF etching rate is preferably 3.00 μm/min or less, 2.00 μm/min or less, 1.00 μm/min or less, 0.75 μm/min or less, 0.70 μm/min or less, 0.65 μm/min or less, and particularly preferably 0.60 μm/min or less. With such an etching rate, the hole diameter hardly expands when through holes are formed, and thus the taper angle can be reduced. As a result, through holes can be formed in the glass substrate at a high density.

The coefficient of thermal expansion in a temperature range of from 30 to 380° C. is preferably from 30×10⁻⁷ to 50×10⁻⁷/° C., more preferably from 32×10⁻⁷ to 48×10⁻⁷/° C., even more preferably from 33×10⁻⁷ to 45×10⁻⁷/° C., even still more preferably from 34×10⁻⁷ to 44×10⁻⁷/° C., and particularly preferably from 35×10⁻⁷ to 43×10⁻⁷/° C. This makes it easy to match the coefficient of thermal expansion of Si used in TFT.

Young's modulus is preferably 65 GPa or more, more preferably 70 Gpa or more, even more preferably 75 Gpa or more, even still more preferably 77 Gpa or more, and particularly preferably 78 Gpa or more. If the Young's modulus is too low, defects due to bending of the glass substrate tend to occur.

The strain point is preferably 650° C. or higher, more preferably 680° C. or higher, more preferably higher than 686° C., and particularly preferably 690° C. or higher. In this way, thermal shrinkage of the glass substrate can be suppressed in a TFT manufacturing process.

Liquid phase temperature is preferably 1350° C. or lower, more preferably lower than 1350° C., even more preferably 1300° C. or lower, and particularly preferably from 1000 to 1280° C. This makes it easy to prevent a situation where devitrified crystals grow during forming, which may reduce productivity. Further, the glass substrate can be easily formed by the overflow down-draw method, and thus the surface quality of the glass substrate can be easily enhanced and the manufacturing cost of the glass substrate can be reduced. Liquid phase temperature is an index of devitrification resistance, and the lower the liquid phase temperature, the better the devitrification resistance.

Liquid phase viscosity is preferably 10^{4.0} dPa·s or more, more preferably 10^{4.1} dPa·s or more, even more preferably 10^{4.2} dPa·s or more, and particularly preferably 10^{4.3} dPa·s or more. In this way, devitrification is less likely to occur during forming, and thus the glass substrate is easily formed by the overflow down-draw method. As a result, the surface quality of the glass substrate can be enhanced, and the manufacturing cost of the glass substrate can be reduced. Liquid phase viscosity is an index of devitrification resistance and formability, and the higher the liquid phase viscosity, the higher the devitrification resistance and formability.

The temperature at which the high-temperature viscosity is 10^{2.5} dPa·s is preferably 1760° C. or lower, more preferably 1700° C. or lower, even more preferably 1690° C. or lower, even still more preferably 1680° C. or lower, and particularly preferably from 1400 to 1670° C. When the temperature at which the high-temperature viscosity is 10^{2.5} dPa·s is too high, it becomes difficult to dissolve the glass batch, and the manufacturing cost of the glass substrate increases. The temperature at which the high-temperature viscosity is 10^{2.5} dPa·s corresponds to the melting temperature, and the lower this temperature is, the better the meltability is.

A β-OH value is an index that indicates the amount of water in glass, and, when the β-OH value is decreased, the strain point can be increased. Further, even when the glass compositions are the same, the smaller the β-OH value, the smaller a thermal shrinkage ratio at a temperature equal to or lower than the strain point. The β-OH value is preferably 0.35/mm or less, more preferably 0.30/mm or less, even more preferably 0.28/mm or less, even still more preferably 0.25/mm or less, and particularly preferably 0.20/mm or less. When the β-OH value is too small, meltability tends to decrease. Therefore, the β-OH value is preferably 0.01/mm or more, and particularly preferably 0.03/mm or more.

Examples of a method for reducing the β-OH value include the following: (1) Selecting a raw material having a low water content. (2) Adding a component (Cl, SO₃ or the like) for lowering the β-OH value to the glass. (3) Reducing the amount of water in a furnace atmosphere. (4) Performing N₂ bubbling in molten glass. (5) Adopting a small melting furnace. (6) Increasing a flow rate of the molten glass. (7) Adopting an electric melting method.

Note that the “β-OH value” refers to a value obtained by substituting a transmittance of glass measured by using FT-IR, in Equation 1 below.

β-OH value=(1/X)log(T₁/T₂) [Equation 1]
X: substrate thickness (mm)
T₁: Transmittance (%) at a reference wavelength of 3846 cm⁻¹
T₂: Minimum transmittance (%) near an absorption wavelength of hydroxyl groups of 3600 cm⁻¹

The glass substrate according to an embodiment of the present invention is preferably formed by the overflow down-draw method. The overflow down-draw method is a method for manufacturing a glass substrate by causing molten glass to overflow from both sides of a heat-resistant trough-shaped structure, and drawing and forming the overflowing molten glass downward while joining the overflowing molten glass at a lower end of the trough-shaped structure. In the overflow down-draw method, the surface to be the surface of the glass substrate does not come into contact with the trough-shaped refractory and is formed in a free surface state. Therefore, it is possible to inexpensively manufacture an unpolished glass substrate with good surface quality, and it is also easy to reduce its thickness.

In addition to the overflow down-draw method, it is also possible to form the glass substrate, for example, by a down-draw method (slot down method or the like), a float method, or the like.

The thickness of the glass substrate according to an embodiment of the present invention is not particularly limited, but is preferably less than 0.7 mm, 0.6 mm or less, or less than 0.6 mm, and particularly preferably from 0.05 to 0.5 mm. As the substrate thickness becomes thinner, a hole diameter of the through holes can be made smaller. This allows the through holes to be made at a high density. The substrate thickness can be adjusted by a flow rate, a sheet drawing speed, or the like during forming.

Thus, the glass substrate according to an embodiment of the present invention is preferably used as a substrate of a micro LED display, particularly a tiling-type micro LED display. In the tiling-type micro LED display, the light emitting elements on the front surface of the glass can be driven from the rear surface of the glass by establishing electrical continuity between the front and rear surfaces of the glass substrate through the through holes. In the glass substrate according to an embodiment of the present invention, through holes can be formed at a high density, and thus a tiling-type micro LED display can have a high definition.

The glass substrate according to an embodiment of the present invention preferably has a through hole, and preferably has a plurality of through holes. This makes it easy to use the glass substrate as a substrate of a micro LED display, particularly a tiling-type micro LED display.

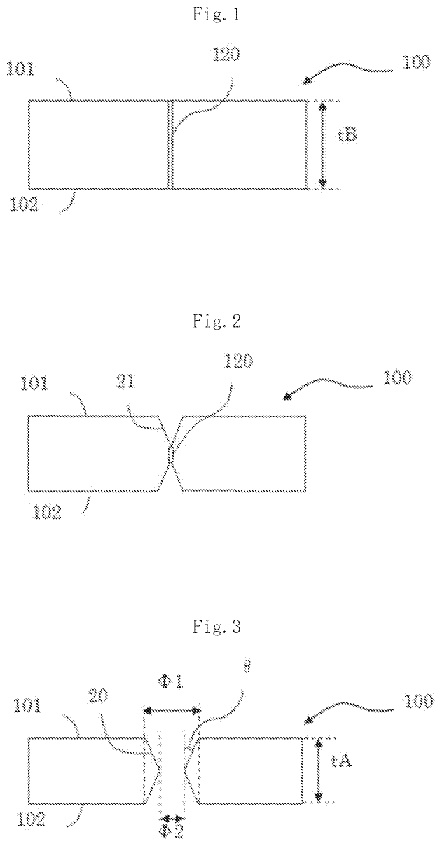

A method for forming the through holes will be described with reference to the drawings. FIG. 1 is a schematic cross-sectional view of a glass substrate having a modified portion formed in the substrate thickness direction. A glass substrate 100 has a first surface 101 and a second surface 102 as main surfaces, and a modified portion 120 is formed so as to penetrate the first surface 101 and the second surface 102 in the substrate thickness direction. The modified portion 120 can be formed by irradiating the glass substrate 100 with femtosecond or picosecond pulsed laser.

For the beam shape of the laser, a Gaussian beam shape or a Bessel beam shape is preferably used, and using a Bessel beam shape is particularly preferred. By setting the beam shape of the laser to the Bessel beam shape, the modified portion 120 can be formed so as to penetrate along the substrate thickness direction in one shot, and thus the time required to form the modified portion can be shortened. The Bessel beam shape can be formed, for example, by using an alkoxy lens.

FIG. 2 is a schematic cross-sectional view of the glass substrate during an etching process. FIG. 3 is a schematic cross-sectional view of a glass substrate with a through hole. Although one modified portion 120 and one through hole 20 are illustrated in FIGS. 1 to 3 for ease of explanation, many modified portions 120 and many through holes 20 are actually provided.

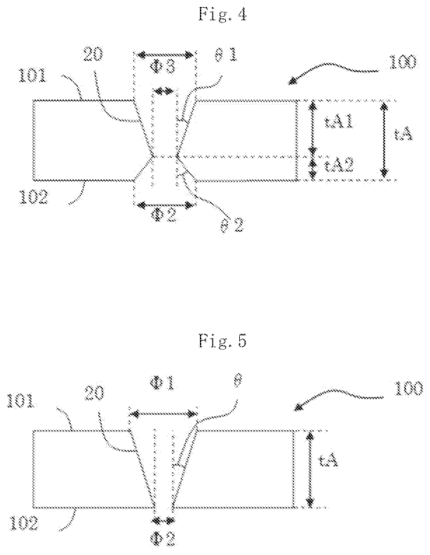

On the glass substrate 100 having a thickness tB and having the modified portion 120, etching is performed both from the first surface 101 and from the first surface 102. As illustrated in FIG. 3, during etching, a modified portion 120 that has not yet been removed exists between a non-through hole 21 extending from the first surface 101 and another non-through hole 21 extending from the first surface 102. As the etching further proceeds, as illustrated in FIG. 4, the hole extending from the first surface 101 and the hole extending from the second surface 102 are connected to form the through hole 20.

The thickness of the glass substrate is reduced from tB to tA by etching, and the modified portion 120 is removed, forming the through holes 20. The through holes 20 have a tapered shape in a cross-sectional view, and its taper angle θ can be calculated from the following Formula 1 using a hole diameter Φ1 in the first surface 101 and the second surface 102, a hole diameter Φ2 in the narrowed portion, and a substrate thickness tA:

θ=arctan((Φ1−Φ2)/tA) Formula 1

The substrate thickness tA after etching and the hole diameter Φ1 in the first surface 101 and the second surface 102 can be measured, for example, by a three-dimensional shape measuring device (for example, a CNC three-dimensional measuring device, available from Mitutoyo Corporation) and a Surfcorder (ET4000A, available from Kosaka Laboratory Ltd.). Alternatively, the substrate thicknesses and the hole diameter described above may be measured by observing the first surface, the second surface, and a cross section of the glass substrate with a transmission light microscope (for example, ECLIPSE LV100ND, which is available from Nikon Corporation) and performing image processing. The hole diameter Φ2 in the narrowed portion is determined as follows. When observing a cross section according to the evaluation method described above, the focus is moved to the inside of the glass and focused on the through hole 20. The length of the narrowed portion is measured based on this image, and the obtained value is defined as the hole diameter Φ2.

When the glass substrate is used in a display application, the taper angle is preferably 13° or less, more preferably 11° or less, even more preferably 10° or less, even still more preferably 9° or less, further preferably 8° or less, and particularly preferably 7° or less. When the taper angle is too large, it becomes difficult to form the through holes at a high density. As a result, it becomes difficult to mount semiconductors on the glass substrate at a high density. The taper angle is preferably 0° or more, more preferably 1° or more, even more preferably 2° or more, even still more preferably 3° or more, further preferably 4° or more, and particularly preferably 5° or more. When the taper angle is too small, it becomes difficult to form a seed layer up to a deep position of the through holes by sputtering during a plating process for forming a conductive portion on the inner walls of the through holes.

A center-to-center distance between the through holes is preferably 200 nm or less, more preferably 160 nm or less, and particularly preferably 100 nm or less. When the center-to-center distance between the through holes is too large, it is difficult to form the through holes at a high density. As a result, it becomes difficult to mount semiconductors on the glass substrate at a high density. The center-to-center distance between the through holes is preferably 1.5 times or more, more preferably 1.7 times or more, and particularly preferably 2.0 times or more the hole diameter. When the center-to-center distance between the through holes is too small, the distance between the hole ends of the through holes is shortened, and the glass substrate is easily damaged from the hole ends.

The type of the etching liquid used in etching is not particularly limited as long as the etching liquid has a higher etching rate for the modified portion 120 than for the glass substrate 100, and, for example, an HF liquid or a KOH liquid is preferably used. As the etching liquid, HF is particularly preferable because of its high etching rate. Alternatively, the etching liquid may be a mixed solution in which one or more of types of acids such as HCl, H₂SO₄, and HNO₃ is/are added to the HF solution. By using such a mixed solution, the deposition of residue on the glass surface and the inner walls of the holes is easier to reduce.

A temperature of the etching liquid is not limited, but a high temperature is effective. In a case in which the etching liquid contains HF, its temperature range is preferably from 0 to 50° C., and more preferably from 20 to 40° C. When the temperature of the etching liquid is increased, the etching rate for the modified portion tends to be relatively increased. As a result, it is possible to shorten the time required to form the through holes, and to decrease the amount of the substrate thickness reduced. Meanwhile, when the temperature of the etching liquid is too high, the volatilization and concentration unevenness of HF occur in the etching liquid, resulting in a large variation in hole shape.

During etching, stirring or ultrasonic waves are preferably applied to the etching liquid. In particular, by applying ultrasonic waves, adhesion and re-deposition of the residue onto the inner walls of the holes can be suppressed. A frequency of the ultrasonic waves is preferably 100 kHz or less, and more preferably 45 kHz or less. This can enhance the effect of ultrasonic cavitation.

FIG. 4 is a schematic cross-sectional view of a glass substrate in which a narrowed portion inside a through hole is not located at a center portion in the substrate thickness direction. Such through holes as illustrated in FIG. 4 can be formed, for example, by performing etching on the first surface 101 of the glass substrate 100, and then subsequently performing etching on the second surface 102 facing the first surface 101. Taper angles θ1 and θ2 at this time can be calculated from the following Equations 2 and 3.

Θ1=arctan((Φ1−Φ3)/(2*tA1)) Equation 2

Θ2=arctan((Φ2−Φ3)/(2*tA2)) Equation 3

FIG. 5 is a schematic cross-sectional view of a glass substrate having no narrowed portion inside a through hole. Through holes as illustrated in FIG. 5 can be formed, for example, by performing etching only on the first surface 101 of the glass substrate 100. A taper angle in this case can be calculated from Equation 4 using the hole diameter Φ1 in the first surface 101, the hole diameter Φ2 in the second surface 102, and the substrate thickness tA.

Θ=arctan((Φ1−Φ2)/(2*tA)) Equation 4

### EXAMPLES

The present invention will be described in detail below based on examples. Note that the following examples are merely illustrative. The present invention is not limited to the following examples in any way.

Table 1 lists Examples (Samples Nos. 1 to 12) of the present invention.

TABLE 1

| | | No. 1 | No. 2 | No. 3 | No. 4 | No. 5 | No. 6 |
|---|---|---|---|---|---|---|---|
| Glass | SiO₂ | 69.7 | 69.9 | 69.9 | 69.9 | 74.6 | 75.3 |
| composition | A1₂O₃ | 10.1 | 10.0 | 10.0 | 10.0 | 5.1 | 5.0 |
| (mol %) | B₂O₃ | 4.9 | 4.8 | 4.8 | 5.0 | 5.0 | 4.8 |
| | Li₂O | <0.001 | <0.001 | <0.001 | <0.001 | <0.001 | <0.001 |
| | Na₂O | 0.011 | 0.011 | 0.011 | <0.011 | <0.011 | 0.011 |
| | K₂O | 0.003 | 0.002 | 0.003 | 0.002 | 0.002 | 0.003 |
| | MgO | 6.1 | 3.1 | 3.0 | 3.0 | 6.1 | 2.9 |
| | CaO | 3.1 | 6.0 | 3.1 | 3.0 | 3.1 | 5.9 |
| | SrO | 3.1 | 3.1 | 6.0 | 3.0 | 3.1 | 3.0 |
| | BaO | 3.0 | 3.0 | 3.1 | 6.0 | 3.0 | 3.0 |
| | SnO₂ | 0.1 | 0.1 | 0.1 | 0.1 | 0.1 | 0.1 |
| | As₂O₃ | <0.005 | <0.005 | <0.005 | <0.005 | <0.005 | <0.005 |
| | Sb₂O₃ | <0.005 | <0.005 | <0.005 | <0.005 | <0.005 | <0.005 |
| | ZnO | 0.0 | 0.0 | 0.0 | 0.0 | 0.0 | 0.0 |
| | P₂O₃ | 0.0 | 0.0 | 0.0 | 0.0 | 0.0 | 0.0 |
| | TiO₂ | 0.0085 | 0.0085 | 0.0078 | 0.0098 | 0.0082 | 0.0083 |
| | Fe₂O₃ | 0.006 | 0.005 | 0.005 | 0.005 | 0.006 | 0.005 |
| | ZrO₂ | <0.001 | <0.001 | <0.001 | <0.001 | 0.001 | 0.001 |
| | Cl | 0.002 | 0.002 | 0.002 | 0.002 | 0.004 | 0.002 |
| | F | <0.07 | <0.07 | <0.07 | <0.07 | <0.07 | <0.07 |

| Li₂O + Na₂O + K₂O | | 0.013 | 0.013 | 0.014 | <0.0014 | <0.0014 | 0.013 |
|---|---|---|---|---|---|---|---|
| Phase separation | | Good | Good | Good | Good | Good | Good |
| Density [g/cm³] | | 2.5658 | 2.5768 | 2.6232 | 2.6589 | 2.5306 | 2.5480 |
| CTE [×10⁻⁷/° C.] | | 37.8 | 40.4 | 41.3 | 41.4 | 37.9 | 40.1 |
| Young's modulus [Gpa] | | Not | Not | Not | Not | Not | Not |
| | | measured | measured | measured | measured | measured | measured |
| Ps [° C.] | | 697 | 690 | 688 | 686 | 687 | 679 |
| Ta [° C.] | | 755 | 747 | 746 | 744 | 744 | 734 |
| Ts [° C.] | | 998 | 991 | 991 | 995 | 1027 | 1023 |
| 10^{4.0} dPa · s [° C.] | | 1340 | 1341 | 1342 | 1354 | 1360 | 1346 |
| 10^{3.0} dPa · s [° C.] | | 1512 | 1516 | 1517 | 1538 | 1556 | 1543 |
| 10^{2.5} dPa · s [° C.] | | 1623 | 1627 | 1629 | 1658 | 1683 | 1671 |
| TL [° C.] | | 1244 | 1215 | 1209 | 1131 | >1304 | >1302 |
| Initial phase | | Cri | Cri | Cri | Cri | Cri | Cri |
| Log₁₀ η TL | | 4.8 | 5.0 | 5.0 | 5.9 | <4.4 | <4.4 |
| HF etching rate [μm/min] | | 0.56 | 0.69 | 0.72 | 0.75 | 1.62 | 1.80 |
| β-OH | | Not | Not | Not | Not | Not | Not |
| | | measured | measured | measured | measured | measured | measured |
| | | No. 7 | No. 8 | No. 9 | No. 10 | No. 11 | No. 12 |
| Glass | SiO₂ | 74.7 | 75.0 | 69.9 | 70.0 | 70.3 | 70.1 |
| composition | A1₂O₃ | 5.0 | 5.0 | 5.0 | 5.1 | 5.0 | 5.0 |
| (mol %) | B₂O₃ | 5.0 | 5.0 | 10.0 | 9.6 | 9.5 | 9.8 |
| | Li₂O | <0.001 | <0.001 | <0.001 | <0.001 | <0.001 | <0.001 |
| | Na₂O | <0.011 | 0.011 | 0.011 | <0.011 | <0.011 | <0.011 |
| | K₂O | 0.002 | 0.003 | 0.002 | 0.002 | 0.002 | 0.002 |
| | MgO | 3.0 | 3.0 | 3.0 | 6.1 | 3.0 | 3.0 |
| | CaO | 3.0 | 3.0 | 3.0 | 3.1 | 6.0 | 3.0 |
| | SrO | 6.0 | 3.0 | 3.0 | 3.1 | 3.0 | 5.9 |
| | BaO | 3.1 | 5.9 | 6.0 | 3.0 | 3.0 | 3.0 |
| | SnO₂ | 0.1 | 0.1 | 0.1 | 0.1 | 0.1 | 0.1 |
| | As₂O₃ | <0.005 | <0.005 | <0.005 | <0.005 | <0.005 | <0.005 |
| | Sb₂O₃ | <0.005 | <0.005 | <0.005 | <0.005 | <0.005 | <0.005 |
| | ZnO | 0.0 | 0.0 | 0.0 | 0.0 | 0.0 | 0.0 |
| | P₂O₃ | 0.0 | 0.0 | 0.0 | 0.0 | 0.0 | 0.0 |
| | TiO₂ | 0.0084 | 0.0086 | 0.0087 | 0.0074 | 0.0075 | 0.0076 |
| | Fe₂O₃ | 0.005 | 0.005 | 0.005 | 0.006 | 0.006 | 0.006 |
| | ZrO₂ | 0.001 | <0.001 | 0.002 | <0.001 | 0.001 | 0.001 |
| | Cl | 0.004 | 0.002 | 0.004 | 0.004 | 0.002 | 0.004 |
| | F | <0.07 | <0.07 | <0.07 | <0.07 | <0.07 | <0.07 |

| | | | | | | |
|---|---|---|---|---|---|---|
| Li₂O + Na₂O + K₂O | <0.0013 | 0.014 | 0.014 | <0.0013 | <0.0013 | <0.0013 |
| Phase separation | Good | Good | Good | Poor | Poor | Poor |
| Density [g/cm³] | 2.5978 | 2.6384 | 2.6315 | 2.5168 | 2.5368 | 2.5875 |
| CTE [×10⁻⁷/° C.] | 41.3 | 41.8 | 42.4 | 38.2 | 40.6 | 41.6 |
| Young's modulus [Gpa] | Not | Not | Not | Not | Not | Not |
| | measured | measured | measured | measured | measured | measured |
| Ps [° C.] | 672 | 663 | 644 | 654 | 652 | 650 |
| Ta [° C.] | 725 | 717 | 689 | 705 | 700 | 695 |
| Ts [° C.] | 1007 | 964 | Not | 1036 | 1044 | 1010 |
| | | | measured | | | |
| 10^{4.0} dPa · s [° C.] | 1332 | 1347 | 1250 | 1283 | 1256 | 1246 |
| 10^{3.0} dPa · s [° C.] | 1526 | 1546 | 1436 | 1468 | 1436 | 1428 |
| 10^{2.5} dPa · s [° C.] | 1654 | 1663 | 1557 | 1588 | 1553 | 1546 |
| TL [° C.] | >1404 | >1402 | 1199 | ≥1246 | ≥1254 | ≥1251 |
| Initial phase | Cri | Cri | Cri | Cri | Cri | Cri |
| Log₁₀ η TL | <3.6 | <3.7 | Not | ≤4.4 | ≤4.0 | ≤4.0 |
| | | | measured | | | |
| HF etching rate [μm/min] | 1.55 | 1.08 | 1.74 | 2.37 | 2.70 | 2.32 |
| β-OH | Not | Not | Not | Not | Not | Not |
| | measured | measured | measured | measured | measured | measured |

First, glass raw materials were mixed to give a glass composition presented in the table, and the glass batch was placed into a platinum crucible and melted at a temperature of from 1600 to 1650° C. for 24 hours. At the time of melting, the glass batch was homogenized by stirring with a platinum stirrer. Next, the molten glass was poured onto a carbon plate, formed into a plate shape, and then gradually cooled at a temperature near the annealing point for 30 minutes. The obtained samples were evaluated for phase separation, density, average coefficient of thermal expansion CTE in a temperature range of from 30 to 380° C., Young's modulus, strain point Ps, annealing point Ta, softening point Ts, temperature at high-temperature viscosity of 10^{4.0} dPa·s, temperature at high-temperature viscosity 10^{3.0} dPa·s, temperature at high-temperature viscosity 10^{2.5} dPa·s, liquid phase temperature TL, initial phase, viscosity log₁₀ ηTL at liquid phase temperature TL, HF etching rate, and β-OH value.

The phase separation was evaluated as “Good” when no cloudiness was visually observed on the glass substrate and as “Poor” when cloudiness was visually observed therein.

The density is a value measured by the well-known Archimedes method.

The average coefficient of thermal expansion CTE in a temperature range of from 30 to 380° C. is a value measured by a dilatometer.

Young's modulus is a value measured by a well-known resonance method.

The strain point Ps, the annealing point Ta, and the softening point Ts are values measured based on methods of ASTM C336 and C338.

The temperatures at which the high-temperature viscosities are 10^{4.0} dPa·s, 10^{3.0} dPa·s, and 10^{2.5} dPa·s are values measured by a platinum sphere pull up method.

The liquid phase temperature TL is a temperature at which crystals are precipitated after glass powder that passed through a standard 30-mesh sieve (500 μm) and remained on a 50-mesh sieve (300 μm) is placed in a platinum boat and then kept for 24 hours in a gradient heating furnace. The crystals were evaluated as the initial phase. In the table, the “Cri” indicates cristobalite.

The liquid phase viscosity log₁₀ ηTL is a value obtained by measuring the viscosity of glass at the liquid phase temperature TL using a platinum sphere pull up method.

The HF etching rate is a value measured by the above-described method.

As is clear from Table 1, Samples Nos. 1 to 12 have a glass composition regulated within a predetermined range, and thus have an HF etching rate of 3.00 μm/min or less. And for each of Samples Nos. 1 to 12, a temperature at which the high-temperature viscosity was 10^{2.5} dPa·s was 1700° C. or lower. Therefore, Samples Nos. 1 to 12 have a low HF etching rate and excellent productivity, and thus are suitable for a substrate of a micro LED display, particularly a tiling-type micro LED display. Samples Nos. 1 to 9 are suitable for a substrate of a micro LED display, particularly a tiling-type micro LED display because the glass is not phase-separated.

Tables 2 to 5 list Examples (Samples Nos. 13 to 61) of the present invention.

TABLE 2

| | | No. 13 | No. 14 | No. 15 | No. 16 | No. 17 | No. 18 |
|---|---|---|---|---|---|---|---|
| Glass | SiO₂ | 72.1 | 72.0 | 71.8 | 72.1 | 72.3 | 72.2 |
| composition | Al₂O₃ | 10.1 | 10.0 | 10.1 | 10.0 | 7.6 | 7.6 |
| (mol %) | B₂O₃ | 4.9 | 5.1 | 5.2 | 4.9 | 7.2 | 7.2 |
| | Li₂O | <0.001 | <0.001 | <0.001 | <0.001 | <0.001 | <0.001 |
| | Na₂O | 0.011 | 0.022 | 0.011 | <0.011 | 0.011 | 0.011 |
| | K₂O | 0.002 | 0.001 | 0.002 | 0.001 | 0.001 | 0.002 |
| | MgO | 5.1 | 2.6 | 2.5 | 2.6 | 5.1 | 2.6 |
| | CaO | 2.6 | 5.1 | 2.5 | 2.6 | 2.6 | 5.1 |
| | SrO | 2.5 | 2.5 | 5.0 | 2.5 | 2.5 | 2.6 |
| | BaO | 2.6 | 2.6 | 2.6 | 5.1 | 2.6 | 2.6 |
| | SnO₂ | 0.1 | 0.1 | 0.1 | 0.1 | 0.1 | 0.1 |
| | As₂O₃ | <0.005 | <0.005 | <0.005 | <0.005 | <0.005 | <0.005 |
| | Sb₂O₃ | <0.005 | <0.005 | <0.005 | <0.005 | <0.005 | <0.005 |
| | ZnO | 0.0 | 0.0 | 0.0 | 0.0 | 0.0 | 0.0 |
| | P₂O₃ | 0.0 | 0.0 | 0.0 | 0.0 | 0.0 | 0.0 |
| | TiO₂ | 0.0101 | 0.0093 | 0.0104 | 0.0105 | 0.0091 | 0.0092 |
| | Fe₂O₃ | 0.006 | 0.006 | 0.006 | 0.005 | 0.006 | 0.006 |
| | ZrO₂ | 0.002 | 0.001 | 0.002 | 0.001 | 0.001 | 0.001 |
| | Cl | 0.002 | 0.004 | 0.004 | 0.004 | 0.004 | 0.002 |
| | F | <0.07 | <0.07 | <0.07 | <0.07 | <0.07 | <0.07 |
| Li₂O + Na₂O + K₂O | | 0.013 | 0.023 | 0.013 | <0.012 | 0.012 | 0.013 |
| Phase separation | | Good | Good | Good | Good | Good | Good |
| Density [g/cm³] | | 2.5122 | 2.5220 | 2.5595 | 2.5926 | 2.4848 | 2.4982 |
| CTE [×10⁻⁷/° C.] | | 34.3 | 36.3 | 38.0 | 38.4 | 34.8 | 36.7 |
| Young's modulus [GPa] | | Not | 74.9 | 74.0 | 73.2 | 72.4 | 72.3 |
| | | measured | | | | | |
| Ps [° C.] | | 706 | 701 | 702 | 698 | 669 | 662 |
| Ta [° C.] | | 768 | 764 | 765 | 763 | 728 | 719 |
| Ts [° C.] | | 1027 | 1023 | 1027 | 1031 | 989 | 977 |
| 10^{4.0} dPa · s [° C.] | | 1390 | 1398 | 1401 | 1404 | 1369 | 1378 |
| 10^{3.0} dPa · s [° C.] | | 1566 | 1578 | 1593 | 1593 | 1560 | 1564 |
| 10^{2.5} dPa · s [° C.] | | 1683 | 1691 | 1731 | 1720 | 1684 | 1673 |
| TL [° C.] | | 1255 | 1233 | 1244 | 1223 | 1229 | 1226 |
| Initial phase | | Cri | Cri | Cri | Cri | Cri | Cri |
| Log₁₀ η TL | | 5.0 | 5.3 | 5.2 | 5.4 | 5.0 | 5.0 |
| HF etching rate [μm/min] | | 0.42 | 0.50 | 0.46 | 0.51 | 0.64 | 0.67 |
| β-OH [/mm] | | 0.16 | Not | Not | Not | Not | Not |
| | | | measured | measured | measured | measured | measured |
| | | No. 19 | No. 20 | No. 21 | No. 22 | No. 23 | No. 24 |
| Glass | SiO₂ | 72.2 | 72.4 | 74.9 | 74.7 | 74.5 | 75.0 |
| composition | Al₂O₃ | 7.5 | 7.5 | 7.5 | 7.5 | 7.5 | 7.4 |
| (mol %) | B₂O₃ | 7.5 | 7.4 | 4.9 | 5.1 | 5.2 | 4.9 |
| | Li₂O | <0.001 | <0.001 | <0.001 | <0.001 | <0.001 | <0.001 |
| | Na₂O | 0.011 | <0.011 | 0.011 | 0.011 | 0.011 | 0.022 |
| | K₂O | 0.001 | 0.002 | 0.002 | 0.001 | 0.001 | 0.003 |
| | MgO | 2.5 | 2.5 | 5.0 | 2.5 | 2.5 | 2.5 |
| | CaO | 2.5 | 2.5 | 2.5 | 5.0 | 2.5 | 2.5 |
| | SrO | 5.0 | 2.5 | 2.5 | 2.5 | 5.0 | 2.5 |
| | BaO | 2.6 | 5.1 | 2.6 | 2.6 | 2.6 | 5.0 |
| | SnO₂ | 0.1 | 0.1 | 0.1 | 0.1 | 0.1 | 0.1 |
| | As₂O₃ | <0.005 | <0.005 | <0.005 | <0.005 | <0.005 | <0.005 |
| | Sb₂O₃ | <0.005 | <0.005 | <0.005 | <0.005 | <0.005 | <0.005 |
| | ZnO | 0.0 | 0.0 | 0.0 | 0.0 | 0.0 | 0.0 |
| | P₂O₃ | 0.0 | 0.0 | 0.0 | 0.0 | 0.0 | 0.0 |
| | TiO₂ | 0.0102 | 0.0113 | 0.0108 | 0.0100 | 0.0093 | 0.0112 |
| | Fe₂O₃ | 0.006 | 0.005 | 0.006 | 0.006 | 0.006 | 0.006 |
| | ZrO₂ | 0.001 | 0.001 | 0.002 | 0.002 | 0.002 | 0.002 |
| | Cl | 0.002 | 0.004 | 0.004 | 0.004 | 0.004 | 0.004 |
| | F | <0.07 | <0.07 | <0.07 | <0.07 | <0.07 | <0.07 |

| | | | | | | |
|---|---|---|---|---|---|---|
| Li₂O + Na₂O + K₂O | 0.012 | <0.012 | 0.013 | 0.012 | 0.012 | 0.025 |
| Phase separation | Good | Good | Good | Good | Good | Good |
| Density [g/cm³] | 2.5367 | 2.5708 | 2.4901 | 2.5032 | 2.5419 | 2.5737 |
| CTE [×10⁻⁷/° C.] | 37.8 | 38.7 | 34.2 | 36.0 | 37.5 | 37.8 |
| Young's modulus [GPa] | 73.3 | 72.5 | 74.1 | 74.0 | Not | 72.3 |
| | | | | | measured | |
| Ps [° C.] | 662 | 654 | 690 | 682 | 682 | 677 |
| Ta [° C.] | 718 | 711 | 752 | 742 | 743 | 738 |
| Ts [° C.] | 977 | 973 | 1025 | 1010 | 1011 | 1010 |
| 10^{4.0} dPa · s [° C.] | 1389 | 1372 | 1419 | 1407 | 1404 | 1406 |
| 10^{3.0} dPa · s [° C.] | 1566 | 1576 | 1616 | 1608 | 1605 | 1600 |
| 10^{2.5} dPa · s [° C.] | 1670 | 1715 | 1754 | 1742 | 1740 | 1721 |
| TL [° C.] | 1210 | 1184 | 1301 | 1308 | 1275 | 1271 |
| Initial phase | Cri | Cri | Cri | Cri | Cri | Cri |
| Log₁₀ η TL | 5.2 | 5.3 | 4.8 | 4.7 | 4.9 | 4.9 |
| HF etching rate [μm/min] | 0.57 | 0.52 | 0.39 | 0.43 | 0.37 | 0.35 |
| β-OH [/mm] | Not | 0.23 | 0.18 | Not | 0.17 | 0.16 |
| | measured | | | measured | | |

TABLE 3

| | | No. 25 | No. 26 | No. 27 | No. 28 | No. 29 | No. 30 |
|---|---|---|---|---|---|---|---|
| Glass | SiO₂ | 74.8 | 74.7 | 74.9 | 74.9 | 72.4 | 72.3 |
| composition | Al₂O₃ | 10.0 | 10.0 | 10.0 | 9.9 | 12.5 | 12.5 |
| (mol %) | B₂O₃ | 2.5 | 2.6 | 2.6 | 2.5 | 2.5 | 2.6 |
| | Li₂O | <0.001 | <0.001 | <0.001 | <0.001 | <0.001 | <0.001 |
| | Na₂O | 0.011 | 0.011 | 0.033 | 0.045 | 0.011 | 0.011 |
| | K₂O | 0.001 | 0.001 | 0.001 | 0.001 | 0.001 | 0.002 |
| | MgO | 5.0 | 2.5 | 2.5 | 2.5 | 4.9 | 2.5 |
| | CaO | 2.5 | 5.0 | 2.5 | 2.5 | 2.5 | 5.0 |
| | SrO | 2.5 | 2.5 | 4.9 | 2.5 | 2.5 | 2.5 |
| | BaO | 2.5 | 2.5 | 2.6 | 5.0 | 2.5 | 2.5 |
| | SnO₂ | 0.1 | 0.1 | 0.1 | 0.1 | 0.1 | 0.1 |
| | As₂O₃ | <0.005 | <0.005 | <0.005 | <0.005 | <0.005 | <0.005 |
| | Sb₂O₃ | <0.005 | <0.005 | <0.005 | <0.005 | <0.005 | <0.005 |
| | ZnO | 0.0 | 0.0 | 0.0 | 0.0 | 0.0 | 0.0 |
| | P₂O₃ | 0.0 | 0.0 | 0.0 | 0.0 | 0.0 | 0.0 |
| | TiO₂ | 0.0092 | 0.0101 | 0.0086 | 0.0096 | 0.0093 | 0.0094 |
| | Fe₂O₃ | 0.007 | 0.006 | 0.006 | 0.006 | 0.007 | 0.006 |
| | ZrO₂ | 0.001 | 0.001 | 0.001 | 0.001 | 0.001 | 0.001 |
| | Cl | 0.002 | 0.002 | 0.004 | 0.002 | 0.002 | 0.002 |
| | F | <0.07 | <0.07 | <0.07 | <0.07 | <0.07 | <0.07 |

| Li₂O + Na₂O + K₂O | 0.012 | 0.012 | 0.035 | 0.046 | 0.012 | 0.013 |
|---|---|---|---|---|---|---|
| Phase separation | Good | Good | Good | Good | Good | Good |
| Density [g/cm³] | 2.5206 | 2.5287 | 2.5652 | 2.5971 | 2.5442 | 2.5507 |
| CTE [×10⁻⁷/° C.] | 33.4 | 35.7 | 36.7 | 37.4 | 33.2 | 35.4 |
| Young's modulus [GPa] | 78.3 | 77.5 | 76.4 | 75.0 | 80.4 | 79.1 |
| Ps [° C.] | 736 | 732 | 729 | 729 | 746 | 748 |
| Ta [° C.] | 799 | 796 | 794 | 794 | 807 | 811 |
| Ts [° C.] | 1063 | 1060 | 1062 | 1066 | 1056 | 1060 |
| 10^{4.0} dPa · s [° C.] | 1427 | 1430 | 1438 | 1447 | 1404 | 1407 |
| 10^{3.0} dPa · s [° C.] | 1603 | 1609 | 1616 | 1631 | 1573 | 1576 |
| 10^{2.5} dPa · s [° C.] | 1710 | 1721 | 1727 | 1743 | 1680 | 1682 |
| TL [° C.] | 1380 | 1303 | 1268 | 1232 | >1383 | 1230 |
| Initial phase | Cri | Cri | Cri | Cri | Mul | Cri |
| Log₁₀ η TL | 4.3 | 4.9 | 5.3 | 5.7 | <4.2 | 5.5 |
| HF etching rate [μm/min] | 0.37 | 0.41 | 0.41 | 0.43 | 0.49 | 0.54 |
| β-OH [/mm] | 0.10 | 0.10 | 0.10 | 0.09 | 0.10 | 0.10 |
| | No. 31 | No. 32 | No. 33 | No. 34 | No. 35 | No. 36 |

| | | | | | | | |
|---|---|---|---|---|---|---|---|
| Glass | SiO₂ | 72.6 | 72.3 | 75.2 | 75.1 | 75.0 | 75.0 |
| composition | Al₂O₃ | 12.4 | 12.4 | 5.0 | 5.0 | 5.0 | 4.9 |
| (mol %) | B₂O₃ | 2.5 | 2.5 | 7.1 | 7.3 | 7.4 | 7.4 |
| | Li₂O | <0.001 | <0.001 | <0.001 | <0.001 | <0.001 | <0.001 |
| | Na₂O | 0.011 | 0.023 | 0.011 | 0.011 | 0.011 | 0.011 |
| | K₂O | 0.002 | 0.003 | 0.001 | 0.001 | 0.001 | 0.001 |
| | MgO | 2.5 | 2.5 | 5.0 | 2.5 | 2.5 | 2.5 |
| | CaO | 2.5 | 2.5 | 2.5 | 5.0 | 2.5 | 2.5 |
| | SrO | 4.9 | 2.5 | 2.5 | 2.5 | 4.9 | 2.5 |
| | BaO | 2.6 | 5.1 | 2.5 | 2.5 | 2.6 | 5.0 |
| | SnO₂ | 0.1 | 0.1 | 0.1 | 0.1 | 0.1 | 0.1 |
| | As₂O₃ | <0.005 | <0.005 | <0.005 | <0.005 | <0.005 | <0.005 |
| | Sb₂O₃ | <0.005 | <0.005 | <0.005 | <0.005 | <0.005 | <0.005 |
| | ZnO | 0.0 | 0.0 | 0.0 | 0.0 | 0.0 | 0.0 |
| | P₂O₃ | 0.0 | 0.0 | 0.0 | 0.0 | 0.0 | 0.0 |
| | TiO₂ | 0.0096 | 0.0097 | 0.0098 | 0.0099 | 0.0100 | 0.0111 |
| | Fe₂O₃ | 0.007 | 0.006 | 0.006 | 0.006 | 0.005 | 0.005 |
| | ZrO₂ | 0.002 | 0.002 | 0.001 | 0.001 | 0.002 | 0.001 |
| | Cl | 0.002 | 0.002 | 0.002 | 0.002 | 0.002 | 0.002 |
| | F | <0.07 | <0.07 | <0.07 | <0.07 | <0.07 | <0.07 |

| | | | | | | |
|---|---|---|---|---|---|---|
| Li₂O + Na₂O + K₂O | 0.013 | 0.026 | 0.012 | 0.011 | 0.011 | 0.012 |
| Phase separation | Good | Good | Good | Good | Good | Good |
| Density [g/cm³] | 2.5872 | 2.6199 | 2.4630 | 2.4792 | 2.5203 | 2.5574 |
| CTE [×10⁻⁷/° C.] | 36.3 | 37.0 | 33.7 | 35.9 | 36.7 | 37.6 |
| Young's modulus [GPa] | 78.5 | 77.7 | 71.0 | 71.6 | 71.6 | 71.2 |
| Ps [° C.] | 748 | 747 | 691 | 686 | 670 | 659 |
| Ta [° C.] | 812 | 812 | 752 | 744 | 724 | 712 |
| Ts [° C.] | 1065 | 1069 | — | — | — | 968 |
| 10^{4.0} dPa · s [° C.] | 1412 | 1423 | 1387 | 1358 | 1353 | 1357 |
| 10^{3.0} dPa · s [° C.] | 1582 | 1592 | 1582 | 1557 | 1552 | 1558 |
| 10^{2.5} dPa · s [° C.] | 1687 | 1697 | 1704 | 1683 | 1677 | 1685 |
| TL [° C.] | 1251 | 1191 | 1272 | 1256 | 1247 | 1249 |
| Initial phase | Ano | Ano | Cri | Cri | Cri | Cri |
| Log₁₀ η TL | 5.3 | 6.0 | — | — | — | 4.7 |
| HF etching rate [μm/min] | 0.57 | 0.59 | 1.84 | 2.09 | 1.80 | 1.44 |
| β-OH [/mm] | 0.09 | 0.09 | 0.14 | 0.13 | 0.15 | 0.12 |

TABLE 4

| | | No. 37 | No. 38 | No. 39 | No. 40 | No. 41 | No. 42 |
|---|---|---|---|---|---|---|---|
| Glass | SiO₂ | 69.9 | 69.9 | 70.0 | 70.0 | 72.3 | 72.4 |
| composition | Al₂O₃ | 12.4 | 12.4 | 12.5 | 12.4 | 10.0 | 7.5 |
| (mol %) | B₂O₃ | 5.0 | 5.0 | 4.8 | 5.0 | 2.6 | 5.0 |
| | Li₂O | <0.001 | <0.001 | <0.001 | <0.001 | <0.001 | <0.001 |
| | Na₂O | 0.011 | 0.011 | 0.011 | 0.023 | 0.011 | 0.021 |
| | K₂O | 0.001 | 0.001 | 0.001 | 0.002 | 0.001 | 0.004 |
| | MgO | 5.0 | 2.5 | 2.5 | 2.5 | 6.0 | 6.0 |
| | CaO | 2.5 | 5.0 | 2.5 | 2.5 | 3.0 | 3.0 |
| | SrO | 2.5 | 2.5 | 5.0 | 2.5 | 3.0 | 3.0 |
| | BaO | 2.5 | 2.5 | 2.6 | 5.0 | 3.0 | 3.0 |
| | SnO₂ | 0.1 | 0.1 | 0.1 | 0.1 | 0.1 | 0.1 |
| | As₂O₃ | <0.005 | <0.005 | <0.005 | <0.005 | <0.005 | <0.005 |
| | Sb₂O₃ | <0.005 | <0.005 | <0.005 | <0.005 | <0.005 | <0.005 |
| | ZnO | 0.0 | 0.0 | 0.0 | 0.0 | 0.0 | 0.0 |
| | P₂O₃ | 0.0 | 0.0 | 0.0 | 0.0 | 0.0 | 0.0 |
| | TiO₂ | 0.010 | 0.009 | 0.009 | 0.011 | 0.009 | 0.009 |
| | Fe₂O₃ | 0.007 | 0.006 | 0.006 | 0.006 | 0.007 | 0.007 |
| | ZrO₂ | 0.001 | 0.001 | 0.001 | 0.001 | 0.002 | 0.003 |
| | Cl | 0.002 | 0.002 | 0.002 | 0.002 | 0.002 | 0.004 |
| | F | <0.07 | <0.07 | <0.07 | <0.07 | <0.07 | <0.07 |
| Li₂O + Na₂O + K₂O | | 0.012 | 0.012 | 0.013 | 0.024 | 0.012 | 0.025 |
| Phase separation | | Good | Good | Good | Good | Good | Good |
| Density [g/cm³] | | 2.5316 | 2.5380 | 2.5738 | 2.6061 | 2.5750 | 2.5426 |
| CTE [×10⁻⁷/° C.] | | 33.7 | 35.6 | 36.8 | 37.2 | 37.4 | 37.8 |
| Young's modulus | | 78.0 | 76.7 | 76.1 | 74.6 | 78.8 | 75.2 |
| [GPa] | | | | | | | |
| Ps [° C.] | | 723 | 723 | 720 | 719 | 719 | 676 |
| Ta [° C.] | | 783 | 783 | 782 | 782 | 779 | 734 |
| Ts [° C.] | | 1025 | 1028 | 1029 | 1034 | 1029 | 986 |
| 10^{4.0} dPa · s [° C.] | | 1358 | 1365 | 1371 | 1380 | 1386 | 1353 |
| 10^{3.0} dPa · s [° C.] | | 1522 | 1528 | 1536 | 1546 | 1570 | 1543 |
| 10^{2.5} dPa · s [° C.] | | 1626 | 1631 | 1639 | 1650 | 1688 | 1654 |
| TL [° C.] | | 1257 | 1173 | 1191 | 1113 | 1319 | 1254 |
| Initial phase | | Mul | Cri | Ano | Ano | Cri | Cri |
| | | | Mul | | | | |
| Log₁₀ η TL | | 4.8 | 5.7 | 5.6 | 6.5 | 4.5 | 4.7 |
| HF etching rate | | 0.59 | 0.66 | 0.72 | 0.75 | 0.49 | 0.66 |
| [μm/min] | | | | | | | |
| β-OH [/mm] | | 0.09 | 0.09 | 0.10 | 0.10 | 0.11 | 0.14 |
| | | No. 43 | No. 44 | No. 45 | No. 46 | No. 47 | No. 48 |
| Glass | SiO₂ | 75.1 | 72.3 | 72.3 | 72.4 | 72.3 | 72.2 |
| composition | Al₂O₃ | 7.4 | 10.0 | 10.0 | 10.0 | 10.0 | 10.0 |
| (mol %) | B₂O₃ | 2.5 | 5.0 | 5.0 | 4.9 | 5.0 | 5.1 |
| | Li₂O | <0.001 | <0.001 | <0.001 | <0.001 | <0.001 | <0.001 |
| | Na₂O | 0.011 | 0.011 | 0.011 | 0.011 | 0.022 | 0.011 |
| | K₂O | 0.005 | 0.001 | 0.001 | 0.001 | 0.002 | 0.001 |
| | MgO | 5.9 | 7.5 | 7.5 | 5.1 | 5.0 | 2.6 |
| | CaO | 3.0 | 2.5 | 0.1 | 5.0 | 0.0 | 7.5 |
| | SrO | 3.0 | 0.0 | 2.5 | 0.0 | 5.0 | 0.0 |
| | BaO | 3.0 | 2.5 | 2.5 | 2.5 | 2.6 | 2.5 |
| | SnO₂ | 0.1 | 0.1 | 0.1 | 0.1 | 0.1 | 0.1 |
| | As₂O₃ | <0.005 | <0.005 | <0.005 | <0.005 | <0.005 | <0.005 |
| | Sb₂O₃ | <0.005 | <0.005 | <0.005 | <0.005 | <0.005 | <0.005 |
| | ZnO | 0.0 | 0.0 | 0.0 | 0.0 | 0.0 | 0.0 |
| | P₂O₃ | 0.0 | 0.0 | 0.0 | 0.0 | 0.0 | 0.0 |
| | TiO₂ | 0.009 | 0.011 | 0.012 | 0.009 | 0.009 | 0.009 |
| | Fe₂O₃ | 0.008 | 0.007 | 0.007 | 0.006 | 0.006 | 0.005 |
| | ZrO₂ | 0.001 | 0.001 | 0.002 | 0.001 | 0.002 | 0.001 |
| | Cl | 0.000 | 0.002 | 0.002 | 0.002 | 0.002 | 0.002 |
| | F | <0.07 | <0.07 | <0.07 | <0.07 | <0.07 | <0.07 |

| | | | | | | |
|---|---|---|---|---|---|---|
| Li₂O + Na₂O + K₂O | 0.016 | 0.012 | 0.012 | 0.012 | 0.024 | 0.012 |
| Phase separation | Good | Good | Good | Good | Good | Good |
| Density [g/cm³] | 2.5554 | 2.4642 | 2.5017 | 2.4722 | 2.5461 | 2.4800 |
| CTE [×10⁻⁷/° C.] | 37.3 | 30.3 | 32.2 | 32.9 | 34.8 | 35.5 |
| Young's modulus | 77.5 | 77.4 | 76.0 | 76.1 | 74.5 | 75.4 |
| [GPa] | | | | | | |
| Ps [° C.] | 707 | 709 | 708 | 702 | 704 | 700 |
| Ta [° C.] | 767 | 770 | 770 | 764 | 766 | 761 |
| Ts [° C.] | 1026 | 1024 | 1027 | 1020 | 1026 | 1019 |
| 10^{4.0} dPa · s [° C.] | 1393 | 1383 | 1398 | 1387 | 1394 | 1391 |
| 10^{3.0} dPa · s [° C.] | 1584 | 1556 | 1572 | 1561 | 1572 | 1569 |
| 10^{2.5} dPa · s [° C.] | 1710 | 1666 | 1681 | 1671 | 1682 | 1672 |
| TL [° C.] | 1346 | Not | Not | Not | Not | Not |
| | | measured | measured | measured | measured | measured |
| Initial phase | Cri | Not | Not | Not | Not | Not |
| | | measured | measured | measured | measured | measured |
| Log₁₀ η TL | 4.3 | Not | Not | Not | Not | Not |
| | | measured | measured | measured | measured | measured |
| HF etching rate | 0.42 | 0.46 | 0.46 | 0.49 | 0.50 | 0.54 |
| [μm/min] | | | | | | |
| β-OH [/mm] | 0.11 | 0.19 | 0.19 | 0.20 | 0.18 | 0.20 |

TABLE 5

| | | No. 49 | No. 50 | No. 51 | No. 52 | No. 53 | No. 54 | No. 55 |
|---|---|---|---|---|---|---|---|---|
| Glass | SiO₂ | 72.3 | 72.1 | 72.7 | 72.2 | 72.3 | 72.4 | 72.3 |
| composition | Al₂O₃ | 10.0 | 10.0 | 9.9 | 10.0 | 10.0 | 10.0 | 10.0 |
| (mol %) | B₂O₃ | 5.0 | 5.1 | 4.7 | 5.2 | 5.0 | 4.9 | 5.0 |
| | Li₂O | <0.001 | <0.001 | <0.001 | <0.001 | <0.001 | <0.001 | <0.001 |
| | Na₂O | 0.011 | 0.011 | 0.022 | 0.011 | 0.022 | 0.022 | 0.022 |
| | K₂O | 0.002 | 0.001 | 0.003 | 0.001 | 0.002 | 0.001 | 0.003 |
| | MgO | 2.5 | 0.1 | 0.0 | 0.0 | 5.0 | 5.0 | 2.5 |
| | CaO | 0.0 | 7.5 | 5.0 | 2.5 | 2.5 | 0.0 | 5.0 |
| | SrO | 7.4 | 2.5 | 5.0 | 7.4 | 0.0 | 2.5 | 0.0 |
| | BaO | 2.6 | 2.5 | 2.6 | 2.6 | 5.0 | 5.1 | 5.0 |
| | SnO₂ | 0.1 | 0.1 | 0.1 | 0.1 | 0.1 | 0.1 | 0.1 |
| | As₂O₃ | <0.005 | <0.005 | <0.005 | <0.005 | <0.005 | <0.005 | <0.005 |
| | Sb₂O₃ | <0.005 | <0.005 | <0.005 | <0.005 | <0.005 | <0.005 | <0.005 |
| | ZnO | 0.0 | 0.0 | 0.0 | 0.0 | 0.0 | 0.0 | 0.0 |
| | P₂O₃ | 0.0 | 0.0 | 0.0 | 0.0 | 0.0 | 0.0 | 0.0 |
| | TiO₂ | 0.0079 | 0.0085 | 0.0087 | 0.0088 | 0.0103 | 0.0096 | 0.0103 |
| | Fe₂O₃ | 0.006 | 0.005 | 0.005 | 0.000 | 0.006 | 0.006 | 0.006 |
| | ZrO₂ | 0.002 | 0.001 | 0.001 | 0.002 | 0.001 | 0.002 | 0.001 |
| | Cl | 0.004 | 0.002 | 0.002 | 0.002 | 0.002 | 0.002 | 0.002 |
| | F | <0.07 | <0.07 | <0.07 | <0.07 | <0.07 | <0.07 | <0.07 |

| | | | | | | | |
|---|---|---|---|---|---|---|---|
| Li₂O + Na₂O + K₂O | 0.014 | 0.012 | 0.025 | 0.013 | 0.024 | 0.024 | 0.025 |
| Phase separation | Good | Good | Good | Good | Good | Good | Good |
| Density [g/cm³] | 2.5920 | 2.5282 | 2.5669 | 2.6045 | 2.5413 | 2.5782 | 2.5490 |
| CTE [×10⁻⁷/° C.] | 38.8 | 39.0 | 39.5 | 40.8 | 34.3 | 35.9 | 36.5 |
| Young's modulus [GPa] | 73.4 | 73.9 | 73.4 | 73.2 | 74.7 | 73.5 | 73.5 |
| Ps [° C.] | 699 | 697 | 694 | 695 | 702 | 705 | 696 |
| Ta [° C.] | 763 | 759 | 755 | 756 | 765 | 768 | 759 |
| Ts [° C.] | 1026 | 1015 | 1018 | 1017 | 1027 | 1034 | 1022 |
| 10^{4.0} dPa · s [° C.] | 1398 | 1379 | 1390 | 1392 | 1400 | 1399 | 1395 |
| 10^{3.0} dPa · s [° C.] | 1579 | 1560 | 1572 | 1576 | 1576 | 1578 | 1577 |
| 10^{2.5} dPa · s [° C.] | 1690 | 1676 | 1684 | 1694 | 1687 | 1690 | 1692 |
| TL [° C.] | Not | Not | Not | Not | Not | Not | Not |
| | measured | measured | measured | measured | measured | measured | measured |
| Initial phase | Not | Not | Not | Not | Not | Not | Not |
| | measured | measured | measured | measured | measured | measured | measured |
| Log₁₀ η TL | Not | Not | Not | Not | Not | Not | Not |
| | measured | measured | measured | measured | measured | measured | measured |
| HF etching rate [μm/min] | 0.58 | 0.56 | 0.57 | 0.59 | 0.49 | 0.50 | 0.52 |
| β-OH [/mm] | 0.17 | 0.20 | 0.23 | 0.17 | 0.18 | 0.16 | 0.19 |

| | | No. 56 | No. 57 | No. 58 | No. 59 | No. 60 | No. 61 |
|---|---|---|---|---|---|---|---|
| Glass | SiO₂ | 72.4 | 72.2 | 72.3 | 72.5 | 72.5 | 72.6 |
| composition | Al₂O₃ | 9.9 | 9.9 | 9.9 | 9.9 | 9.9 | 9.8 |
| (mol %) | B₂O₃ | 5.0 | 5.1 | 5.0 | 4.9 | 5.0 | 4.9 |
| | Li₂O | <0.001 | <0.001 | <0.001 | <0.001 | <0.001 | <0.001 |
| | Na₂O | 0.023 | 0.023 | 0.023 | 0.034 | 0.023 | 0.023 |
| | K₂O | 0.002 | 0.002 | 0.002 | 0.002 | 0.002 | 0.002 |
| | MgO | 2.5 | 0.1 | 0.0 | 2.5 | 2.5 | 0.0 |
| | CaO | 0.0 | 5.0 | 2.5 | 2.5 | 0.0 | 2.5 |
| | SrO | 5.0 | 2.5 | 5.0 | 0.0 | 2.5 | 2.5 |
| | BaO | 5.1 | 5.0 | 5.1 | 7.6 | 7.5 | 7.5 |
| | SnO₂ | 0.1 | 0.1 | 0.1 | 0.1 | 0.1 | 0.1 |
| | As₂O₃ | <0.005 | <0.005 | <0.005 | <0.005 | <0.005 | <0.005 |
| | Sb₂O₃ | <0.005 | <0.005 | <0.005 | <0.005 | <0.005 | <0.005 |
| | ZnO | 0.0 | 0.0 | 0.0 | 0.0 | 0.0 | 0.0 |
| | P₂O₃ | 0.0 | 0.0 | 0.0 | 0.0 | 0.0 | 0.0 |
| | TiO₂ | 0.0098 | 0.0106 | 0.0099 | 0.0116 | 0.0090 | 0.0091 |
| | Fe₂O₃ | 0.005 | 0.005 | 0.004 | 0.005 | 0.005 | 0.005 |
| | ZrO₂ | 0.001 | 0.001 | 0.001 | 0.001 | 0.001 | 0.001 |
| | Cl | 0.002 | 0.002 | 0.004 | 0.002 | 0.002 | 0.002 |
| | F | <0.07 | <0.07 | <0.07 | <0.07 | <0.07 | <0.07 |

| | | | | | | |
|---|---|---|---|---|---|---|
| Li₂O + Na₂O + K₂O | 0.025 | 0.025 | 0.025 | 0.037 | 0.025 | 0.026 |
| Phase separation | Good | Good | Good | Good | Good | Good |
| Density [g/cm³] | 2.6254 | 2.5984 | 2.6355 | 2.6185 | 2.6566 | 2.6703 |
| CTE [×10⁻⁷/° C.] | 38.5 | 39.9 | 41.1 | 38.6 | 40.1 | 41.9 |
| Young's modulus [GPa] | 72.5 | 73.1 | 72.5 | 72.3 | 71.8 | 71.9 |
| Ps [° C.] | 697 | 692 | 689 | 694 | 694 | 684 |
| Ta [° C.] | 761 | 755 | 752 | 758 | 759 | 747 |
| Ts [° C.] | 1029 | 1019 | 1015 | 1028 | 1030 | 1015 |
| 10^{4.0} dPa · s [° C.] | 1408 | 1391 | 1397 | 1414 | 1407 | 1399 |
| 10^{3.0} dPa · s [° C.] | 1588 | 1572 | 1582 | 1600 | 1587 | 1588 |
| 10^{2.5} dPa · s [° C.] | 1698 | 1685 | 1694 | 1718 | 1695 | 1708 |
| TL [° C.] | Not | Not | Not | Not | Not | Not |
| | measured | measured | measured | measured | measured | measured |
| Initial phase | Not | Not | Not | Not | Not | Not |
| | measured | measured | measured | measured | measured | measured |
| Log₁₀ η TL | Not | Not | Not | Not | Not | Not |
| | measured | measured | measured | measured | measured | measured |
| HF etching rate [μm/min] | 0.56 | 0.57 | 0.61 | 0.59 | 0.66 | 0.68 |
| β-OH [/mm] | 0.16 | 0.18 | 0.17 | 0.18 | 0.16 | 0.19 |

First, glass raw materials were mixed to give a glass composition presented in the table, and the glass batch was placed into a platinum crucible and melted at a temperature of from 1650 to 1680° C. for 24 hours. At the time of melting, the glass batch was homogenized by stirring with a platinum stirrer. Next, the molten glass was poured onto a carbon plate, formed into a plate shape, and then gradually cooled at a temperature near the annealing point for 30 minutes. The obtained samples were evaluated for phase separation, density, average coefficient of thermal expansion CTE in a temperature range of from 30 to 380° C., Young's modulus, strain point Ps, annealing point Ta, softening point Ts, temperature at high-temperature viscosity of 10^{4.0} dPa·s, temperature at high-temperature viscosity 10^{3.0} dPa·s, temperature at high-temperature viscosity 10^{2.5} dPa·s, liquid phase temperature TL, initial phase, viscosity log₁₀ ηTL at liquid phase temperature TL, HF etching rate, and β-OH value by the above-described methods. In the table, the “Mul” indicates mullite and “Ano” indicates anorthite.

Samples Nos. 13 to 61 had a glass composition regulated within a predetermined range, and thus had an HF etching rate of 3.00 μm/min or less, and the glass was not phase-separated. Thus, Samples Nos. 13 to 61 are suitable for a substrate of a micro LED display, particularly a tiling-type micro LED display.

Furthermore, fine holes were formed in Samples Nos. 1, 4 to 5, 8 to 10, and 24 to 43 by the following method, and the taper angle of the holes was confirmed.

First, each glass substrate having a rectangular surface of 35 mm×20 mm and a thickness of 500 μm was prepared. The glass substrate was irradiated by a femtosecond pulse laser shaped into a Bessel beam at a pitch interval of 160 μm, forming approximately 5000 modified portions in a region of 12.8 mm×9.6 mm at the center portion of the glass substrate.

Next, the glass substrate was etched for a predetermined period of time. Specifically, the glass substrate was placed in a PP test tube containing an etching liquid, and etching was performed with ultrasonic waves applied to the etching liquid, resulting in formation of holes in the glass substrate. At this time, a Teflon (registered trademark) jig was used to fix the glass substrate with the glass substrate being 40 mm away from the bottom of the test tube. The shape of the through holes formed and the shape of the glass substrate were as illustrated in FIG. 4, and the shape parameters were measured by the methods described above using a transmission light microscope (ECLIPSE LV100ND, which is available from Nikon Corporation).

The etching liquid used a mixed acid of 2.5 mol/L HF solution and 1.0 mol/L HCl solution, and the temperature of the etching liquid was set to 30° C. To prevent the temperature from rising during the application of ultrasonic waves, a chiller was used to circulate the water in the ultrasonic device and keep the water temperature at 30° C. An ultrasonic cleaner (VS-100III, which is available from AS ONE Corporation) was used to apply ultrasonic waves. Using this ultrasonic cleaner, ultrasonic waves of 28 kHz were applied to the etching liquid.

The thickness of the prepared glass substrate, the shape of the glass substrate after etching, and the shape of the hole formed by etching are shown in Tables 6 to 14. The “HF etching rate” in the tables is a value shown in Tables 1 to 5, and was measured for 2.5 mol/L of HF solution. Meanwhile, in etching to form the holes, an acid mixture of 2.5 mol/L HF solution and 1.0 mol/L HCl solution was used as the etching liquid, and ultrasound was applied. Therefore, the etching rate at the time of forming the holes is different from the “HF etching rate” in the tables.

TABLE 6

| Glass sample | No. 1 | No. 1 | No. 1 | No. 4 | No. 4 | No. 4 | No. 5 | No. 5 |
|---|---|---|---|---|---|---|---|---|
| Etching time [min] | 10 | 20 | 40 | 10 | 20 | 30 | 10 | 15 |
| Through or Non-through | Non- | Non- | Through | Non- | Non- | Through | Non- | Non- |
| | through | through | | through | through | | through | through |
| Substrate thickness before | 500 | 500 | 500 | 500 | 500 | 500 | 500 | 500 |
| etching | | | | | | | | |
| tB [μm] | | | | | | | | |
| Substrate thickness after | 482 | 466 | 432 | 474 | 447 | 423 | 450 | 434 |
| etching | | | | | | | | |
| tA [μm] | | | | | | | | |
| Amount of substrate | 18 | 34 | 68 | 26 | 53 | 77 | 50 | 66 |
| thickness reduced Δt [μm] | | | | | | | | |
| Hole Diameter Φ1 [μm] | 17 | 31 | 57 | 20 | 34 | 62 | 32 | 45 |
| Hole diameter Φ2 [μm] | 17 | 30 | 56 | 18 | 33 | 61 | 29 | 42 |
| Hole diameter Φ3 [μm] of | 0 | 0 | 3 | 0 | 0 | 2 | 0 | 0 |
| narrowed portion inside | | | | | | | | |
| through hole | | | | | | | | |
| Hole depth tA1 [μm] | 113 | 173 | 216 | 114 | 152 | 212 | 100 | 118 |
| Hole depth tA2 [μm] | 90 | 146 | 216 | 89 | 145 | 212 | 86 | 115 |
| Taper angle θ1 [°] | 4.4 | 5.2 | 7.2 | 4.9 | 6.4 | 8.1 | 9.2 | 10.7 |
| Taper angle θ2 [°] | 5.4 | 5.9 | 7.1 | 5.8 | 6.5 | 8.0 | 9.7 | 10.5 |
| Average taper angle θ [°] | 4.9 | 5.5 | 7.1 | 5.4 | 6.5 | 8.0 | 9.4 | 10.6 |
| ((θ1 + θ2)/2) | | | | | | | | |
| HF etching rate [μm/min] | 0.56 | 0.56 | 0.56 | 0.75 | 0.75 | 0.75 | 1.62 | 1.62 |

TABLE 7

| Glass sample | No. 8 | No. 8 | No. 8 | No. 9 | No. 9 | No. 9 | No. 10 | No. 10 |
|---|---|---|---|---|---|---|---|---|
| Etching time [min] | 10 | 20 | 30 | 5 | 10 | 15 | 5 | 10 |
| Through or Non-through | Non- | Non- | Non- | Non- | Non- | Non- | Non- | Non- |
| | through | through | through | through | through | through | through | through |
| Substrate thickness before | 500 | 500 | 500 | 500 | 500 | 500 | 500 | 500 |
| etching | | | | | | | | |
| tB [μm] | | | | | | | | |
| Substrate thickness after | 469 | 442 | 412 | 477 | 453 | 431 | 472 | 442 |
| etching | | | | | | | | |
| tA [μm] | | | | | | | | |
| Amount of substrate thickness | 31 | 58 | 88 | 23 | 47 | 69 | 28 | 58 |
| reduced Δt [μm] | | | | | | | | |
| Hole Diameter Φ1 [μm] | 24 | 44 | 64 | 22 | 36 | 52 | 24 | 44 |
| Hole diameter Φ2 [μm] | 24 | 43 | 62 | 21 | 35 | 45 | 19 | 45 |
| Hole diameter Φ3 [μm] of | 0 | 0 | 0 | 0 | 0 | 0 | 0 | 0 |
| narrowed portion inside | | | | | | | | |
| through hole | | | | | | | | |
| Hole depth tA1 [μm] | 99 | 144 | 193 | 59 | 89 | 115 | 63 | 93 |
| Hole depth tA2 [μm] | 88 | 143 | 192 | 63 | 103 | 123 | 47 | 88 |
| Taper angle θ1 [°] | 6.8 | 8.6 | 9.5 | 10.7 | 11.4 | 12.8 | 10.5 | 13.5 |
| Taper angle θ2 [°] | 7.9 | 8.6 | 9.2 | 9.5 | 9.6 | 10.4 | 11.4 | 14.3 |
| Average taper angle θ [°] | 7.3 | 8.6 | 9.3 | 10.1 | 10.5 | 11.6 | 11.0 | 13.9 |
| ((θ1 + θ2)/2) | | | | | | | | |
| HF etching rate [μm/min] | 1.08 | 1.08 | 1.08 | 1.74 | 1.74 | 1.74 | 2.37 | 2.37 |

TABLE 8

| Glass sample | No. 10 | No. 24 | No. 24 | No. 24 | No. 25 | No. 25 | No. 25 | No. 26 |
|---|---|---|---|---|---|---|---|---|
| Etching time [min] | 15 | 10 | 20 | 40 | 10 | 20 | 30 | 10 |
| Through or Non-through | Non- | Non- | Non- | Through | Non- | Non- | Non- | Non- |
| | through | through | through | | through | through | through | through |
| Substrate thickness before | 500 | 500 | 500 | 500 | 500 | 500 | 500 | 500 |
| etching | | | | | | | | |
| tB [μm] | | | | | | | | |
| Substrate thickness after | 411 | 485 | 472 | 457 | 492 | 480 | 472 | 492 |
| etching | | | | | | | | |
| tA [μm] | | | | | | | | |
| Amount of substrate thickness | 89 | 15 | 28 | 43 | 8 | 20 | 28 | 8 |
| reduced Δt [μm] | | | | | | | | |
| Hole diameter Φ1 [μm] | 60 | 15 | 26 | 42 | 9 | 21 | 28 | 13 |
| Hole diameter Φ2 [μm] | 50 | 14 | 25 | 42 | 9 | 21 | 28 | 9 |
| Hole diameter Φ3 [μm] of | 0 | 0 | 0 | 1 | 0 | 0 | 0 | 0 |
| narrowed portion inside | | | | | | | | |
| through hole | | | | | | | | |
| Hole depth tA1 [μm] | 103 | 112 | 174 | 231 | 109 | 158 | 199 | 105 |
| Hole depth tA2 [μm] | 110 | 87 | 126 | 225 | 38 | 130 | 166 | 26 |
| Taper angle θ1 [°] | 16.3 | 3.7 | 4.2 | 5.1 | 2.5 | 3.7 | 4.1 | 3.4 |
| Taper angle θ2 [°] | 12.8 | 4.5 | 5.6 | 5.2 | 6.8 | 4.5 | 4.8 | 10.1 |
| Average taper angle θ [°] | 14.6 | 4.1 | 4.9 | 5.1 | 4.6 | 4.1 | 4.4 | 6.8 |
| ((θ1 + θ2)/2) | | | | | | | | |
| HF etching rate [μm/min] | 2.37 | 0.35 | 0.35 | 0.35 | 0.37 | 0.37 | 0.37 | 0.41 |

TABLE 9

| Glass sample | No. 26 | No. 26 | No. 27 | No. 27 | No. 27 | No. 28 | No. 28 | No. 28 |
|---|---|---|---|---|---|---|---|---|
| Etching time [min] | 20 | 30 | 10 | 20 | 30 | 10 | 20 | 30 |
| Through or Non-through | Non- | Non- | Non- | Non- | Non- | Non- | Non- | Non- |
| | through | through | through | through | through | through | through | through |
| Substrate thickness before | 500 | 500 | 500 | 500 | 500 | 500 | 500 | 500 |
| etching | | | | | | | | |
| tB [μm] | | | | | | | | |
| Substrate thickness after | 480 | 472 | 492 | 479 | 472 | 486 | 473 | 465 |
| etching | | | | | | | | |
| tA [μm] | | | | | | | | |
| Amount of substrate thickness | 20 | 28 | 8 | 21 | 28 | 14 | 27 | 35 |
| reduced Δt [μm] | | | | | | | | |
| Hole Diameter Φ1 [μm] | 23 | 30 | 12 | 24 | 32 | 13 | 25 | 32 |
| Hole diameter Φ2 [μm] | 22 | 30 | 12 | 23 | 31 | 12 | 25 | 32 |
| Hole diameter Φ3 [μm] of | 0 | 0 | 0 | 0 | 0 | 0 | 0 | 0 |
| narrowed portion inside | | | | | | | | |
| through hole | | | | | | | | |
| Hole depth tA1 [μm] | 155 | 196 | 97 | 154 | 193 | 95 | 155 | 192 |
| Hole depth tA2 [μm] | 92 | 154 | 38 | 112 | 159 | 50 | 128 | 170 |
| Taper angle θ1 [°] | 4.2 | 4.4 | 3.7 | 4.4 | 4.7 | 4.0 | 4.6 | 4.8 |
| Taper angle θ2 [°] | 6.7 | 5.5 | 8.8 | 5.9 | 5.6 | 7.2 | 5.5 | 5.4 |
| Average taper angle θ [°] | 5.5 | 5.0 | 6.2 | 5.2 | 5.1 | 5.6 | 5.1 | 5.1 |
| ((θ1 + θ2)/2) | | | | | | | | |
| HF etching rate [μm/min] | 0.41 | 0.41 | 0.41 | 0.41 | 0.41 | 0.43 | 0.43 | 0.43 |

TABLE 10

| Glass sample | No. 29 | No. 29 | No. 29 | No. 30 | No. 30 | No. 30 | No. 31 | No. 31 |
|---|---|---|---|---|---|---|---|---|
| Etching time [min] | 10 | 20 | 30 | 10 | 20 | 30 | 10 | 20 |
| Through or Non-through | Non- | Non- | Non- | Non- | Non- | Non- | Non- | Non- |
| | through | through | through | through | through | through | through | through |
| Substrate thickness before | 500 | 500 | 500 | 500 | 500 | 500 | 500 | 500 |
| etching | | | | | | | | |
| tB [μm] | | | | | | | | |
| Substrate thickness after | 495 | 491 | 483 | 485 | 468 | 460 | 488 | 475 |
| etching | | | | | | | | |
| tA [μm] | | | | | | | | |
| Amount of substrate thickness | 5 | 9 | 17 | 15 | 32 | 40 | 12 | 25 |
| reduced Δt [μm] | | | | | | | | |
| Hole Diameter Φ1 [μm] | 14 | 26 | 35 | 15 | 28 | 38 | 15 | 31 |
| Hole diameter Φ2 [μm] | 13 | 25 | 34 | 14 | 27 | 37 | 16 | 30 |
| Hole diameter Φ3 [μm] of | 0 | 0 | 0 | 0 | 0 | 0 | 0 | 0 |
| narrowed portion inside | | | | | | | | |
| through hole | | | | | | | | |
| Hole depth tA1 [μm] | 107 | 164 | 197 | 99 | 155 | 198 | 82 | 154 |
| Hole depth tA2 [μm] | 50 | 155 | 178 | 85 | 154 | 188 | 98 | 144 |
| Taper angle θ1 [°] | 3.6 | 4.6 | 5.0 | 4.3 | 5.2 | 5.5 | 5.3 | 5.7 |
| Taper angle θ2 [°] | 7.7 | 4.7 | 5.4 | 4.9 | 5.0 | 5.6 | 4.6 | 6.0 |
| Average taper angle θ [°] | 5.7 | 4.6 | 5.2 | 4.6 | 5.1 | 5.5 | 4.9 | 5.8 |
| ((θ1 + θ2)/2) | | | | | | | | |
| HF etching rate [μm/min] | 0.49 | 0.49 | 0.49 | 0.54 | 0.54 | 0.54 | 0.57 | 0.57 |

TABLE 11

| Glass sample | No. 31 | No. 32 | No. 32 | No. 32 | No. 33 | No. 33 | No. 34 | No. 34 |
|---|---|---|---|---|---|---|---|---|
| Etching time [min] | 30 | 10 | 20 | 30 | 10 | 20 | 10 | 20 |
| Through or Non-through | Non- | Non- | Non- | Non- | Non- | Non- | Non- | Non- |
| | through | through | through | through | through | through | through | through |
| Substrate thickness before | 500 | 500 | 500 | 500 | 500 | 500 | 500 | 500 |
| etching | | | | | | | | |
| tB [μm] | | | | | | | | |
| Substrate thickness after | 462 | 485 | 471 | 457 | 466 | 430 | 459 | 418 |
| etching | | | | | | | | |
| tA [μm] | | | | | | | | |
| Amount of substrate thickness | 38 | 15 | 29 | 43 | 34 | 70 | 41 | 82 |
| reduced Δt [μm] | | | | | | | | |
| Hole Diameter Φ1 [μm] | 40 | 16 | 31 | 40 | 32 | 56 | 33 | 57 |
| Hole diameter Φ2 [μm] | 39 | 17 | 31 | 40 | 33 | 56 | 36 | 61 |
| Hole diameter Φ3 [μm] of | 0 | 0 | 0 | 0 | 0 | 0 | 0 | 0 |
| narrowed portion inside | | | | | | | | |
| through hole | | | | | | | | |
| Hole depth tA1 [μm] | 192 | 103 | 150 | 188 | 83 | 129 | 74 | 112 |
| Hole depth tA2 [μm] | 182 | 92 | 143 | 188 | 78 | 117 | 83 | 118 |
| Taper angle θ1 [°] | 5.9 | 4.5 | 5.9 | 6.1 | 10.8 | 12.3 | 12.4 | 14.4 |
| Taper angle θ2 [°] | 6.1 | 5.4 | 6.1 | 6.0 | 11.9 | 13.5 | 12.1 | 14.5 |
| Average taper angle θ [°] | 6.0 | 5.0 | 6.0 | 6.1 | 11.4 | 12.9 | 12.2 | 14.4 |
| ((θ1 + θ2)/2) | | | | | | | | |
| HF etching rate [μm/min] | 0.57 | 0.59 | 0.59 | 0.59 | 1.84 | 1.84 | 2.09 | 2.09 |

TABLE 12

| Glass sample | No. 35 | No. 35 | No. 36 | No. 36 | No. 37 | No. 37 | No. 37 | No. 38 |
|---|---|---|---|---|---|---|---|---|
| Etching time [min] | 10 | 20 | 10 | 20 | 10 | 20 | 30 | 10 |
| Through or Non-through | Non- | Non- | Non- | Non- | Non- | Non- | Non- | Non- |
| | through | through | through | through | through | through | through | through |
| Substrate thickness before | 500 | 500 | 500 | 500 | 500 | 500 | 500 | 500 |
| etching | | | | | | | | |
| tB [μm] | | | | | | | | |
| Substrate thickness after | 466 | 435 | 479 | 452 | 486 | 467 | 455 | 481 |
| etching | | | | | | | | |
| tA [μm] | | | | | | | | |
| Amount of substrate thickness | 34 | 65 | 21 | 48 | 14 | 33 | 45 | 19 |
| reduced Δt [μm] | | | | | | | | |
| Hole Diameter Φ1 [μm] | 32 | 55 | 29 | 50 | 16 | 30 | 41 | 17 |
| Hole diameter Φ2 [μm] | 34 | 53 | 29 | 48 | 16 | 29 | 32 | 18 |
| Hole diameter Φ3 [μm] of | 0 | 0 | 0 | 0 | 0 | 0 | 0 | 0 |
| narrowed portion inside | | | | | | | | |
| through hole | | | | | | | | |
| Hole depth tA1 [μm] | 81 | 114 | 80 | 126 | 121 | 166 | 209 | 115 |
| Hole depth tA2 [μm] | 68 | 116 | 75 | 133 | 88 | 150 | 196 | 44 |
| Taper angle θ1 [°] | 11.3 | 13.5 | 10.1 | 11.2 | 3.8 | 5.2 | 5.6 | 4.3 |
| Taper angle θ2 [°] | 14.2 | 12.8 | 11.1 | 10.2 | 5.2 | 5.5 | 4.7 | 11.7 |
| Average taper angle θ [°] | 12.7 | 13.1 | 10.6 | 10.7 | 4.5 | 5.4 | 5.2 | 8.0 |
| ((θ1 + θ2)/2) | | | | | | | | |
| HF etching rate [μm/min] | 1.80 | 1.80 | 1.44 | 1.44 | 0.59 | 0.59 | 0.59 | 0.66 |

TABLE 13

| Glass sample | No. 38 | No. 38 | No. 39 | No. 39 | No. 39 | No. 40 | No. 40 | No. 40 |
|---|---|---|---|---|---|---|---|---|
| Etching time [min] | 20 | 30 | 10 | 20 | 30 | 10 | 20 | 30 |
| Through or Non-through | Non- | Non- | Non- | Non- | Non- | Non- | Non- | Non- |
| | through | through | through | through | through | through | through | through |
| Substrate thickness before | 500 | 500 | 500 | 500 | 500 | 500 | 500 | 500 |
| etching | | | | | | | | |
| tB [μm] | | | | | | | | |
| Substrate thickness after | 463 | 448 | 480 | 456 | 442 | 482 | 466 | 443 |
| etching | | | | | | | | |
| tA [μm] | | | | | | | | |
| Amount of substrate thickness | 37 | 52 | 20 | 44 | 58 | 18 | 34 | 57 |
| reduced Δt [μm] | | | | | | | | |
| Hole Diameter Φ1 [μm] | 32 | 45 | 18 | 34 | 48 | 18 | 35 | 51 |
| Hole diameter Φ2 [μm] | 31 | 45 | 18 | 33 | 47 | 20 | 34 | 48 |
| Hole diameter Φ3 [μm] of | 0 | 0 | 0 | 0 | 0 | 0 | 0 | 0 |
| narrowed portion inside | | | | | | | | |
| through hole | | | | | | | | |
| Hole depth tA1 [μm] | 161 | 199 | 104 | 159 | 198 | 108 | 157 | 207 |
| Hole depth tA2 [μm] | 113 | 177 | 58 | 134 | 186 | 66 | 143 | 184 |
| Taper angle θ1 [°] | 5.8 | 6.5 | 4.8 | 6.2 | 6.9 | 4.6 | 6.3 | 7.0 |
| Taper angle θ2 [°] | 7.9 | 7.2 | 8.8 | 7.1 | 7.2 | 8.5 | 6.8 | 7.5 |
| Average taper angle θ [°] | 6.8 | 6.9 | 6.8 | 6.6 | 7.1 | 6.6 | 6.5 | 7.2 |
| ((θ1 + θ2)/2) | | | | | | | | |
| HF etching rate [μm/min] | 0.66 | 0.66 | 0.72 | 0.72 | 0.72 | 0.75 | 0.75 | 0.75 |

TABLE 14

| Glass sample | No. 41 | No. 41 | No. 41 | No. 42 | No. 42 | No. 42 | No. 43 | No. 43 | No. 43 |
|---|---|---|---|---|---|---|---|---|---|
| Etching time [min] | 10 | 20 | 30 | 10 | 20 | 30 | 10 | 20 | 40 |
| Through or Non- | Non- | Non- | Non- | Non- | Non- | Non- | Non- | Non- | Through |
| through | through | through | through | through | through | through | through | through | |
| Substrate thickness | 500 | 500 | 500 | 500 | 500 | 500 | 500 | 500 | 500 |
| before etching | | | | | | | | | |
| tB [μm] | | | | | | | | | |
| Substrate thickness | 482 | 464 | 450 | 479 | 459 | 440 | 490 | 480 | 458 |
| after etching | | | | | | | | | |
| tA [μm] | | | | | | | | | |
| Amount of substrate | 18 | 36 | 50 | 21 | 41 | 60 | 10 | 20 | 42 |
| thickness reduced Δt | | | | | | | | | |
| [μm] | | | | | | | | | |
| Hole Diameter Φ1 | 15 | 27 | 38 | 18 | 34 | 47 | 13 | 22 | 42 |
| [μm] | | | | | | | | | |
| Hole diameter Φ2 | 13 | 26 | 37 | 18 | 33 | 47 | 13 | 22 | 42 |
| [μm] | | | | | | | | | |
| Hole diameter Φ3 | 0 | 0 | 0 | 0 | 0 | 0 | 0 | 0 | 0 |
| [μm] of narrowed | | | | | | | | | |
| portion inside | | | | | | | | | |
| through hole | | | | | | | | | |
| Hole depth tA1 [μm] | 97 | 169 | 216 | 105 | 172 | 219 | 101 | 154 | 242 |
| Hole depth tA2 [μm] | 81 | 166 | 214 | 93 | 172 | 218 | 72 | 137 | 216 |
| Taper angle θ1 [°] | 4.3 | 4.6 | 5.0 | 4.8 | 5.7 | 6.1 | 3.7 | 4.1 | 5.0 |
| Taper angle θ2 [°] | 4.7 | 4.4 | 4.9 | 5.4 | 5.4 | 6.1 | 5.0 | 4.5 | 5.5 |
| Average taper angle | 4.5 | 4.5 | 5.0 | 5.1 | 5.6 | 6.1 | 4.4 | 4.3 | 5.2 |
| θ [°] | | | | | | | | | |
| ((θ1 + θ2)/2) | | | | | | | | | |
| HF etching rate | 0.49 | 0.49 | 0.49 | 0.66 | 0.66 | 0.66 | 0.42 | 0.42 | 0.42 |
| [μm/min] | | | | | | | | | |

From these results, it can be seen that the smaller the HF etching rate, the smaller the taper angle when the fine holes are formed. In addition, it can be seen that the smaller the HF etching rate, the harder it is to increase the taper angle even when the etching time is increased to increase the hole depth.

### REFERENCE SIGNS LIST

100 Glass substrate
101 First surface
100 Second surface
120 Modified portion
20 Through hole
21 Non-through hole

1. A glass substrate comprising a glass composition containing from 65.0 to 80.0 mol % of SiO₂, from 2.0 to 15.0 mol % of Al₂O₃, from 0 to 15.0 mol % of B₂O₃, from 0.001 to less than 0.1 mol % of Li₂O+Na₂O+K₂O, from 0 to 15.0 mol % of MgO, from 0 to 15.0 mol % of CaO, from 0 to 15.0 mol % of SrO, from 0 to 15.0 mol % of BaO, from 0 to 1.0 mol % of SnO₂, from 0 to less than 0.050 mol % of As₂O₃, and from 0 to less than 0.050% of Sb₂O₃.

2. The glass substrate according to claim 1, wherein the glass composition contains from 69.6 to 80.0 mol % of SiO₂, from 7.1 to 13.0 mol % of Al₂O₃, from 2.0 to 7.5 mol % of B₂O₃, from 0.001 to less than 0.1 mol % of Li₂O+Na₂O+K₂O, from 3.4 to 10.0 mol % of MgO, from 0.1 to 5.5 mol % of CaO, from 0.1 to 15.0 mol % of SrO, from 0.3 to 3.0 mol % of BaO, from 0.01 to 1.0 mol % of SnO₂, from 0 to less than 0.050 mol % of As₂O₃, and from 0 to less than 0.050 mol % of Sb₂O₃.

3. The glass substrate according to claim 1, wherein the glass composition contains from 69.6 to 80.0 mol % of SiO₂, from 7.1 to 12.5 mol % of Al₂O₃, from 2.7 to 7.5 mol % of B₂O₃, from 0.001 to less than 0.1 mol % of Li₂O+Na₂O+K₂O, from 3.4 to 10.0 mol % of MgO, from 0.1 to 5.5 mol % of CaO, from 0.5 to 3.8 mol % of SrO, from 0.3 to 3.0 mol % of BaO, from 0.01 to 1.0 mol % of SnO₂, from 0 to less than 0.050 mol % of As₂O₃, and from 0 to less than 0.050 mol % of Sb₂O₃.

4. The glass substrate according to claim 1, wherein the glass composition contains from 69.7 to 80.0 mol % of SiO₂, from 2.0 to 15.0 mol % of Al₂O₃, from 2.5 to 15.0 mol % of B₂O₃, from 0.001 to less than 0.1 mol % of Li₂O+Na₂O+K₂O, from 0 to 15.0 mol % of MgO, from 0 to 8.2 mol % of CaO, from 0 to 15.0 mol % of SrO, from 1.1 to 15.0 mol % of BaO, from 0.01 to 1.0 mol % of SnO₂, from 0.0005 to 0.1 mol % of TiO₂, from 0 to less than 0.050% of As₂O₃, and from 0 to less than 0.050 mol % of Sb₂O₃.

5. The glass substrate according to claim 1, wherein the glass substrate has an HF etching rate of 3.00 μm/min or less.

6. The glass substrate according to claim 1, wherein a temperature at which a high-temperature viscosity is 10^{2.5} dPa·s is 1760° C. or lower.

7. The glass substrate according to claim 1, comprising a through hole.

8. The glass substrate according to claim 1, wherein the glass substrate is for use in a micro LED display.
